(19) United States
(12) Patent Application Publication
(10) Pub. No.: US 2010/0050737 A1
(43) Pub. Date: Mar. 4, 2010

(54) SEPARATION TECHNOLOGY METHOD AND IDENTIFICATION OF ERROR

(76) Inventor: Andrew Mark Wolters, Raleigh, NC (US)

Correspondence Address: PASSE' INTELLECTUAL PROPERTY, LLC, 1717 BRASSFIELD RD., RALEIGH, NC, 27614, US

(21) Appl. No.: 12/548,950

(22) Filed: Aug. 27, 2009

Related U.S. Application Data
(60) Provisional application No. 61/093,444, filed on Sep. 1, 2008.

(51) Int. Cl. G01N 37/00; G01N 1/28; G01N 30/00; B01D 57/02; H01J 49/26; G01J 3/00; G01N 21/47; G01N 21/76; G06F 15/00; G01R 33/48

(52) U.S. Cl. 73/23.22; 73/23.2; 73/61.43; 73/23.35; 73/61.52; 204/450; 204/451; 250/282; 356/51; 356/337; 436/172; 73/61.57; 702/127; 324/307

(57) ABSTRACT

The present invention relates to a method and accompanying device for separating a known or unknown sample into one or more subsamples. By comparing the subsample's measurement profile data to the sample measurement profile data, the performance of the separation can be determined. The separation could be chromatography [such as high-performance liquid chromatography (HPLC), gas chromatography (GC), or the like], electrophoresis [such as capillary electrophoresis (CE) or the like], or another separation technique. The measurement profile data could be ultraviolet/visible (UV/Vis) spectra, mass spectra (MS), or another measurement technique.

This application claims priority of U.S. provisional application No. 61/093,444 filed on Sep. 1, 2008 and is incorporated herein in its entirety by reference.

### COPYRIGHT NOTICE

A portion of the disclosure of this patent contains material that is subject to copyright protection. The copyright owner has no objection to the reproduction by anyone of the patent document or the patent disclosure as it appears in the Patent and Trademark Office patent files or records, but otherwise reserves all copyright rights whatsoever.

### BACKGROUND OF THE INVENTION

1. Field of the Invention

The present invention relates to a method for separating a sample into one or more components. In particular the present invention relates to the separating of one or more components of a mixture in a manner to identify potential errors in separation of the one or more components.

2. Description of Related Art

For over a century, separation technology has proved indispensable for providing critical chemical and biochemical information as well as serving as a preparatory method for isolating components. Separation technology enables the user to separate the individual components from a sample for subsequent detection for purposes of identification (and frequently quantitation). Separation technology is also useful for determining the purity of samples. Consequently, separation technology has made a substantial impact in a plethora of scientific and technological areas.

Examples of separation technology include: liquid chromatography used to check for impurities in pharmaceutical products, gas chromatography used to detect pollutants in water, and electrophoresis used for analyzing DNA. Though each of the types of separation technology are different, they share common features including introducing a sample and subjecting the sample to some form of separation into one or more components, and typically detecting the separated sample components with a measurement technique.

Of the more popular separation technologies, chromatography is based upon the passing of the sample in a mobile phase through a stationary phase and electrophoresis is based upon component mobility in an electric field. After the sample has been subjected to a separation technique, a detector is used to record measurement profile data (MPD). Two popular detection techniques are ultraviolet/visible (UV/Vis) spectroscopy and mass spectrometry (MS).

These separation techniques are not without their problems and limitations, however. Due to the ubiquitous utility of separation technology, a substantial amount of research and development has focused on overcoming those problems and limitations. One of the primary limitations of separation technology is the co-elution of different sample components, wherein the components in the overlapped peaks often cannot be distinguished. Various advances have been made to resolve this problem. In one approach, the traditional single-measurement-point detector (i.e. measurement of a single variable) is replaced by a multiple-measurement-point detector (i.e. measurement of multiple variables, oftentimes simultaneous). Since co-eluting sample components might produce different signals, the multiple-measurement-point detector allows more potential discriminating power for separation technology. As an example, the traditional UV/Vis detector measures light absorption at a single set wavelength (such as 254 nm) at a given time; this type of detector can be replaced by a UV/Vis diode array detector which can measure light absorption at multiple wavelengths (such as from 190 nm to 700 nm with 2 nm resolution) simultaneously. In another approach, multiple detectors are used to measure a sample after separation rather than just measurement by a single detector; for example, a sample subjected to a separation technique is sequentially analyzed by a UV/Vis diode array detector and a MS detector. In another approach, multiple separation stages are used to separate the individual components from a mixture; as an example of this approach, ion-exchange chromatography is subsequently followed by reverse-phase chromatography prior to detection. In still another approach, chemometric and other computer-based data processing techniques are used to analyze the measurement data collected after separation. One way this is accomplished is where the measurement data collected after separation is analyzed by partial least squares (PLS) to identify potential co-elution of sample components.

In addition to the problem of co-elution of different sample components, other limitations and problems such as analysis run time and sensitivity have also received substantial attention in research and development to improve performance. However, there are other limitations and problems in separation technology that have not been adequately addressed.

In separation technology, one critical problem is where the desired sample component might not reach (or only partially reach) the detector after being subjected to the separation technique during the method run time. If the sample component does not reach the detector after the sample is subjected to separation, the sample component will not be identified and the interpretation of the experiment can be invalid, perhaps critically. A situation might exist where a cross-contaminant in a pharmaceutical drug might not be detected wherein the contaminant could be detrimental or even fatal to the patient taking the drug with the unknown contaminant. Unfortunately, this type of problem can arise across all different types of separation techniques. In chromatography, a sample component (or sample components) can be retained by the stationary phase so strongly that they are not eluted from the stationary phase before the end of the method run. Sometimes a peak retained during one run will elute during a subsequent run, leading to a contaminant peak. Moreover, sometimes one or more sample components will be retained by the stationary phase so strongly that they cannot be eluted with any of the different mobile phases used in the particular separation technique.

In capillary electrophoresis, one or more sample components can migrate too slowly towards the detector and not reach the detector before the timed end of the run. In fact, sometimes a sample component(s) will not reach the detector since they migrate in the opposite direction toward the capillary inlet. In performing capillary electrophoresis, usually a positive electric potential is applied to the capillary inlet where sample is injected, and a negative electric potential is applied to the outlet (often done by grounding the outlet) at or close to where the sample is detected. In this mode, cationic components migrate strongly towards the detector. Ideally, anionic components are pushed towards the detector by electro-osmotic flow despite their electrical repulsion. In practice, sometimes anionic components do not reach the detector since their electrical repulsion is too strong for the electro-osmotic flow to overcome.

Another critical problem in separation technology is sample component degradation during separation. This can occur when one or more sample components are degraded during chromatography due to chemical interaction with the stationary phase or mobile phase. A sample component can also be degraded during chromatography due to the temperature, which is often-times elevated deliberately or naturally during the chromatographic process. In electrophoresis, the applied voltage causes Joule heating, which can lead to sample component degradation. Other factors can cause sample degradation. If even only a fraction of a sample component suffers degradation during the separation process, the sample component can be mis-identified or mis-quantified. While degradation during separation can occur for small molecules, it is a very common problem for biological molecules, such as peptides and proteins.

Yet another critical problem in separation technology occurs when there is inefficient separation of the sample component (or sample components) during the separation process. In chromatography, a sample component might experience little or no retention on the stationary phase and instead elute with the injected sample solvent (also known as the void volume). In UV/Vis detection with a traditional flow cell (such as a bubble-flow cell or the like), differences in the index of refraction between the solvent of the injected sample and the mobile phase will result in changing the optical path length when the injected solvent reaches the detector, thereby causing a “false peak” (also known as the void volume peak) in the UV/Vis measurement data. If a sample component is insufficiently retained by the stationary phase in chromatography and elutes with the sample solvent, the sample component might be hidden by the “false peak” of the void volume and not be identified. If a sample component elutes with the sample solvent and is not identified, the interpretation of the process can be in error.

Yet another critical problem occurs in separation technology when contaminant peaks from the instrument appear along with the sample during the analysis. The occurrence of contaminant peaks can lead to erroneous results. Contaminant peaks can arise from a number of sources. As an example, the separation solution (or mobile phase, carrier gas, buffer solution or electrolyte) could have a contaminant present. As another example, the instrument could be contaminated from residual sample from a prior analysis (also known as sample carry-over). As another example, in chromatography, a sample component (or sample components) can be retained by the chromatographic column so strongly that it is not eluted during its run but is eluted in a later run as a contaminant peak.

It is clear that the above and other problems can occur when taking a sample and subjecting it to a separation. The current state-of-the-art method to investigate extraneous errors in the performance of this task is through parallel separations, wherein a sample (or an aliquot or aliquots thereof) is subjected to two or more distinct separations to obtain subsample measurement profile data after each separation. In addition to referring to separations done in parallel, parallel separations can also refer to separations done sequentially (such as from different sample aliquot injections) and can also refer to separations conducted on separate devices. Afterwards, the number of separation (chromatographic) peaks in each separation are counted to investigate if there is a discrepancy in number of peaks between separations. As an example, a sample is subjected to HPLC on a C18 chromatographic column with measurement data collected after separation and the same sample (or another aliquot thereof) is subjected to HPLC on a silica chromatographic column with measurement data collected after separation. Continuing the example, the chromatographic peaks are counted in the chromatogram from the C18 column separation and the chromatographic peaks are counted in the chromatogram from the silica column separation. Continuing the example, the number of chromatographic peaks in the two separations are compared. If the number of peaks between the separations are equal, then each method is deemed to have adequately analyzed the sample. However, if the number of peaks between the separations are not equal, then at least one of the methods is deemed to have failed to adequately analyze the sample. In practice, usually parallel chromatography is reserved for method validation due to time, labor, and instrument constraints. Thus, parallel chromatography is used to analyze a “representative” sample (or samples) and validate one separation method for analyzing future (other) samples.

Of course, parallel separations have several problems. Obviously, a sample component that is troublesome for one separation method can also be troublesome for other separation methods. Moreover, the different separations could have problems with different sample components which can obfuscate performance determination. As an example, one sample component might be excessively retained (not reach the detector during the method run time) on the first separation method while another sample component might be excessively retained (not reach the detector during the method run time) on the second separation; yet, in this example, the same number of separation (chromatographic peaks) might be counted for the two distinct separations and, thereby, the separations could be incorrectly deemed valid. Furthermore, parallel separations can struggle with identifying sample component degradation during separation because the method is based on counting separation (chromatographic) peaks. Of course, if parallel chromatography is only used for method validation on a “representative” sample (or samples), any new sample components (such as an unexpected impurity) that arise in future (other) samples can be improperly analyzed by the selected method since it was not designed for them. Due to these issues, an alternative or complementary technique is needed to investigate the performance of separations.

### BRIEF SUMMARY OF THE INVENTION

The present invention relates to the use of the discovery that one can identify many of the aforementioned problems of separation technology, as practiced on current instrumentation, by analyzing the sample before-hand and then analyzing the sample components after separation and making sure that nothing has been lost or added or degraded in the separation process.

Accordingly, in one aspect of the invention there is, a method for analyzing a sample comprising:
a) measuring the sample to obtain measurement profile data of the sample;
b) applying a separation technique to the sample to separate it into one or more subsamples;
c) measuring at least one of the one or more subsamples to obtain measurement profile data; and
d) comparing the subsample measurement profile data to the sample measurement profile data.

In another aspect of the present invention there is a method for analyzing a sample comprising:
a) measuring the sample to obtain measurement profile data of the sample;
b) applying a separation technique to the sample to separate it into one or more subsamples; and
c) measuring at least one of the one or more subsamples to obtain measurement profile data.

In yet another aspect of the invention there is a device for analyzing a sample comprising:
a) a means for measuring the sample to obtain measurement profile data of the sample;
b) a means for applying a separation technique to the sample to separate the sample into one or more subsamples;
c) a means for measuring at least one of the subsamples to obtain measurement profile data of; and
d) a means for comparing the subsample measurement profile data and the sample measurement profile data.

In yet another aspect of the invention there is a device for analyzing a sample comprising:
a) a means for measuring the sample to obtain measurement profile data of the sample;
b) applying a separation technique to the sample to separate it into one or more subsamples; and
c) a means for measuring at least one of the subsamples in a specialty flow cell to obtain measurement profile data.

In another aspect of the invention there is a device for analyzing a sample comprising:
a) a means for measuring the sample to obtain measurement profile data of the sample;
b) applying a separation technique to the sample to separate it into one or more subsamples; and
c) a means for measuring at least one of the subsamples at a different device detection location to obtain measurement profile data.

In another aspect of the invention there is a method for analyzing a sample comprising:
a) applying a separation technique to the sample to separate it into one or more subsamples;
b) measuring at least one of the one or more subsamples to obtain measurement profile data;
c) repeating steps a) and b) for each separation comprising the parallel separations; and
d) comparing the subsample measurement profile data from the parallel separations to one another by using a method selected from the group comprising, comparing composite subsample measurement profile data, determining the difference spectrum between two subsample measurement profile data.

### BRIEF DESCRIPTION OF THE DRAWINGS

FIG. 1a depicts a flow chart for one embodiment of the present invention.

FIG. 1b depicts a flow chart for one embodiment of the present invention.

FIG. 2 depicts a HPLC device capable of conducting an embodiment of the invention method.

FIG. 3 depicts a HPLC device capable of conducting an embodiment of the invention method.

FIG. 4 depicts the UV/Vis absorbance spectra for sample components A, B, and C.

FIG. 5 depicts the experimental results for the HPLC-UV/Vis analysis of the sample mixture.

FIG. 6 depicts the difference UV/Vis spectrum.

FIG. 7 depicts HPLC-UV/Vis-MS device capable of conducting an embodiment of the invention method.

FIG. 8 depicts the experimental results for the LC-MS analysis from the scout separation.

FIG. 9 depicts the experimental results for the LC-MS analysis from the comprehensive separation of the sample.

FIG. 10 depicts a HPLC device capable of conducting an embodiment of the invention method.

### DETAILED DESCRIPTION OF THE INVENTION

While this invention is susceptible to embodiment in many different forms, there is shown in the drawings and will herein be described in detail specific embodiments, with the understanding that the present disclosure of such embodiments is to be considered as an example of the principles and not intended to limit the invention to the specific embodiments shown and described. In the description below, like reference numerals are used to describe the same, similar or corresponding parts in the several views of the drawings. This detailed description defines the meaning of the terms used herein and specifically describes embodiments in order for those skilled in the art to practice the invention.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of items, functions, steps or acts are in some way inherently mutually exclusive.

The drawings featured in the figures are for the purpose of illustrating certain convenient embodiments of the present invention, and are not to be considered as limitation thereto. Term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

As used herein the term “sample” refers to any chemical or biological sample which can be the subject of separation analysis. The sample could be a single component (example given, if the sample is an unknown at the time of separation) or the sample could be a mixture of 2 or more components. Oftentimes, a sample consisting of a single component will be analyzed by separation technology to determine purity. The components can be elements, ions, compounds, organic compositions, biological or the like. For analysis with a separation technique, the sample will be in a liquid-state, or a gas-state, or dissolved in a solvent state. The sample could be dissolved in a solvent to enable analysis on a device used to conduct the method of the invention. As an example, a solid mixture of different organic compounds (the sample) could be dissolved in a liquid to enable high-performance liquid chromatography (HPLC) analysis. The solvent used to dissolve the sample could be a pure liquid or it could be a mixture of liquids. Examples of solvents used to prepare samples for separation analysis include but are not limited to: water, methanol, acetonitrile and the like but will obviously depend on the sample being analyzed. Even with an unknown sample one skilled in the art can often find appropriate solvents without undue experimentation. In addition to solvents, other chemicals can be added to the sample solution to facilitate analysis. As an example, buffers can be added to the sample solution to control pH. As another example, ion-pairing agents such as trifluoroacetic acid could be used to facilitate separation of cations on charge-neutral chromatographic columns. Of course, these chemical additives could be added to the separation solution (or mobile phase, carrier gas, buffer solution, or electrolyte). The sample can also be chemically modified to facilitate separation analysis. As an example, non-fluorescent sample components can be chemically reacted with fluorescent dyes to enable fluorometric detection of the sample components in a separation. The sample will be subjected to a separation technique for identifying, separating or the like one or more of the individual components comprising the sample. For purposes of this invention, an aliquot of a sample is also the “sample.” As used herein “applying a separation technique to the sample” refers to a technique which involves the separation of one or more components comprising the sample by any of the generally known separation techniques such as chromatography and electrophoresis.

The sample could undergo off-line preparatory separations prior to introduction to the device for analysis by the method of the invention. The off-line preparatory separation can facilitate separation analysis by removing species that are not of interest and might in fact be detrimental to the device or the analysis. As an example, particulate matter in a sample solution can clog the chromatographic column if injected for HPLC. To avoid this problem, the sample solution can be decanted or filtered or centrifuged to remove the particulate matter from the sample solution before injection onto the HPLC instrument. Any separation technique can be used as an off-line preparatory separation for a sample to be subsequently analyzed on a device by the method of the invention. Types of off-line preparatory separations include but are not limited to: decanting, filtration, centrifugation, solid-phase extraction, liquid-liquid extraction, dialysis and preparatory chromatography. Multiple off-line preparatory separations can be used to prepare the sample for analysis. Of course, any preparatory separation carries the risk of losing sample components of interest or adding contaminants and should be conducted carefully. For purposes of this invention, a sample collected after a preparatory separation is also the “sample.”

As an alternative or complement to off-line preparatory separations, on-line sample pre-treatment (i.e. sample pre-treatment conducted on the device used to conduct the method of the invention) can be conducted on the sample prior to measuring the sample to obtain measurement profile data of the sample or prior to the separation. For current state-of-the art, sample pre-treatment is optionally used on the device prior to subjecting the sample to separation and subsequent collection of subsample measurement profile data (i.e. for current state-of-the-art, measurement profile data is not collected after sample pre-treatment but only after separation). As an embodiment of the invention, sample measurement profile data can be collected before sample pre-treatment or after sample pre-treatment (but prior to the separation). The same sample (or portion thereof) that undergoes sample pre-treatment does not have to undergo the separation. Sample pre-treatment includes, but is not limited to, one or more of the following: sieve, frit, trap column, guard column, or the like. As an example of sample pre-treatment, the device could have a sieve present before the chromatographic column to remove any particulate matter from the sample solution prior to separation. As another example, a trap column could be used on the device to separate components of interest from possible interfering species that are not of interest before subjecting the sample to the chromatographic column. As another example, a guard column could be used on the device to prevent contamination of the chromatographic column to extend its lifetime. Multiple sample pre-treatments can be used to prepare the sample. Of course, some types of sample pre-treatment carry the risk of losing sample components of interest or adding contaminants, and should be conducted carefully. For purposes of this invention, a sample obtained after sample pre-treatment is also the “sample.”

For purposes of this invention, a sample component (or components) can refer to the “subsample” or part of the sample, depending on the context. For purposes of this invention, a sample consisting of one component is a “subsample” after separation. For purposes of this invention, a sample consisting of a single component that is subjected to a separation experiences a “separation.” This could happen, for example, where a pure single component is subjected to a separation technique. The result would be a single subsample, which could then be used to indicate the sample component's purity. For purposes of this invention, if the separation technique fails to deliver a single sample component to the detector so that the measurement data consists only of noise (i.e. no detectable signal peaks), the measurement data collected after subjecting the sample to separation is still considered subsample measurement profile data.

When the claims refer to a “single device” it is meant that the method of the present invention is carried out in a single device, instrument, machine, analyzer or the like, as opposed to conducting the analysis in two or more devices (unless networked together or the like to have them act as a single device) or in separate hand or mechanical means which requires separation of the method between devices. For the purpose of this invention, a “single device,” in addition to referring to a stand-alone device, also refers to a modified device, a modular device, and two or more devices networked together or to a common computer (either through a physical or wireless connection or through a data-storage device).

For purposes of this invention, “UV/Vis” refers to UV (ultraviolet) or Vis (visible) as well as UV/Vis. Thus, UV/Vis measurement can refer to UV measurement, Vis measurement, or UV/Vis measurement. For purposes of this invention, UV/Vis can refer to single-measurement-point detection or multiple-measurement-point-detection. Moreover, for purposes of this invention, UV/Vis is inclusive of the different types of detectors such as including but not limited to: diode array detection, diode, photomultiplier tube, charge-coupled device.

For purposes of this invention, MS can refer to mass spectrometry with any ionization source, any detector type, and any mode of operation.

For purposes of this invention, “HPLC” can refer to high-performance liquid chromatography (abbreviated as HPLC), high-pressure liquid chromatography (abbreviated as HPLC), liquid chromatography (LC), ultra-high pressure liquid chromatography (abbreviated as uHPLC or uPLC), fast liquid chromatography, or other names well known in the field.

For purposes of this invention, the “separation solution”, depending upon the particular type of separation, can also be referred to as mobile phase, carrier gas, buffer solution, electrolyte or other names well known in the field. For purposes of this invention, “electrophoresis” can also refer to capillary electrophoresis, capillary zone electrophoresis, micellar electrophoresis, micellar electrokinetic capillary chromatography, isotachophoresis, gel electrophoresis, electrochromatography, and other types of electrophoresis well known in the field.

For purposes of this invention, “the separation column”, depending upon the particular type of separation, can also be referred to as the separation channel or chromatographic column.

For purposes of the present invention, other scientific and technical terms also refer inclusively to synonyms and particular types.

The method of the present invention starts with the device performing a measurement on the sample. The measuring process of the sample is for the purpose of obtaining measurement profile data of the sample. “Measurement profile data” refers to a quantitative or qualitative analysis that produces information or data about the sample to be analyzed in a separation technology technique. For example, in one embodiment, an ultraviolet/visible (UV/Vis) spectrum of the sample could be obtained to serve as measurement profile data. Other analytical methods for producing data for measurement profile data include mass spectrometry (MS).

By the phrase “applying a separation technique to the sample to separate it into one or more subsamples” refers to using one (or more than one of the separation techniques for multiple-stage separations) of the separation techniques to separate the sample into one or more of its comprising components. The subsample can contain a single component or multiple components (overlapped peaks) depending upon the particular analytical method. Examples of separation techniques include chromatography and electrophoresis as well as other separating techniques discussed elsewhere herein. “Separating” can also refer to attempted separation where an attempt to separate a sample occurs but in reality the separation does not occur.

Another step in the method of the present invention involves “measuring at least one of the one or more subsamples to obtain measurement profile data.” Each of the subsamples could be measured or less than all could be measured. The measurement profile data from the subsamples in most cases will be the same type of measurement profile data as the sample measurement profile data. In one embodiment where a UV/Vis spectrum is obtained from the sample, a UV/Vis spectrum is obtained for the subsamples. The separation test result at this point is checked by comparing the subsample measurement profile data to the sample measurement profile data. In the embodiment above, the UV/Vis spectrum of the sample can be compared to the UV/Vis spectra from all of the subsample UV/Vis spectra. In one embodiment, multiple different measurement profile data could be taken for the sample and subsamples.

Lastly, the subsample measurement profile data and the sample measurement profile data are compared to determine if there is any (significant) difference between them. A (significant) difference between measurement profile data then serves as an indication of potential error in the performance of the separation which either has to be accounted for or is an indication that the separation process was in enough error that it cannot be relied upon.

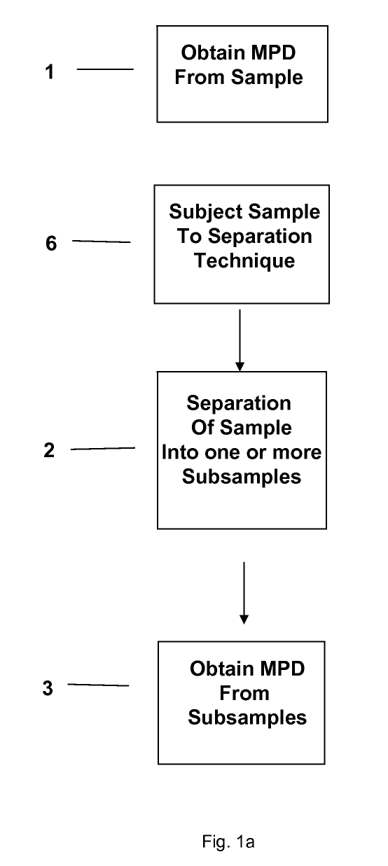

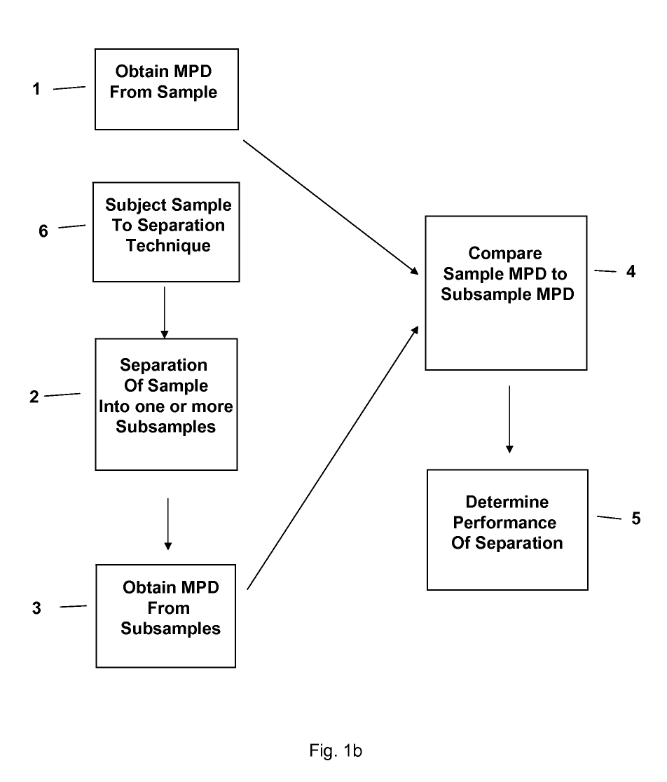

FIG. 1 depicts a flow chart of an embodiment of the invention method. As seen in FIG. 1, the chronological order of the method steps can be changed to any logical sequence. Thus, for the embodiment of the invention method, the measurement profile data from the sample could be collected before, during or after the sample separation and subsequent collection of measurement profile data from the subsamples. The claims of this disclosure cover any logical sequence of steps.

Instruments for Use with the Present Invention

The present invention method can use any device which can accomplish separation technology and achieve the comparison techniques described herein. In one embodiment, the device can be a stand-alone instrument (i.e. a single instrument collects measurement profile data from a sample, separates the sample into subsamples, collects measurement profile data from the subsamples, and makes the necessary comparisons). A computer can operate the device and perform the comparison of measurement profile data from the sample and from the subsamples. For the purposes of this invention, a computer that is used to control all or part of the operation of the device is part of the device, including data analysis. As an alternative or complement, measurement profile data can be transferred (either through a physical or wireless network connection or through a data-storage device) to a separate computer for subsequent comparison. For the purposes of this invention, a computer that is used to compare measurement data from the device is also part of the device. The device can be a modular instrument where an auxiliary instrument unit is used in addition to the main instrument to collect measurement profile data from a sample or subsamples, to make comparisons of measurement profile data, or to separate the sample into subsamples. The device can be a modified instrument, such that an additional component or additional components and/or other modifications are added to an instrument that was previously incapable of performing the entire method of the present invention. The device can be a collection of networked instruments that perform the steps of the present invention. The device can be a collection of instruments in which measurement profile data is transferred to a common computer. However, in general any collection of integrated or non-integrated means of performing each of the steps of the present invention can be utilized.

The invention can use any appropriate equipment for performing the steps. One skilled in the art can, in view of the disclosure herein, determine the equipment necessary to perform the steps of the invention. One can use different equipment and/or parts for collecting the different measurement profile data (i.e. measurement profile data from the sample and measurement profile data from the subsamples) and/or can share similar equipment and/or parts for collecting the different measurement profile data (i.e. measurement profile data from the sample and measurement profile data from the subsamples) along with changes in features such as optical path, fluid flow path, or any other features or the like.

To better illustrate the types of devices that can be used to perform the method of the invention, two embodiments will be described. The drawings featured in the figures are for the purpose of illustrating certain convenient embodiments of the present invention, and are not to be considered as limitation thereto.

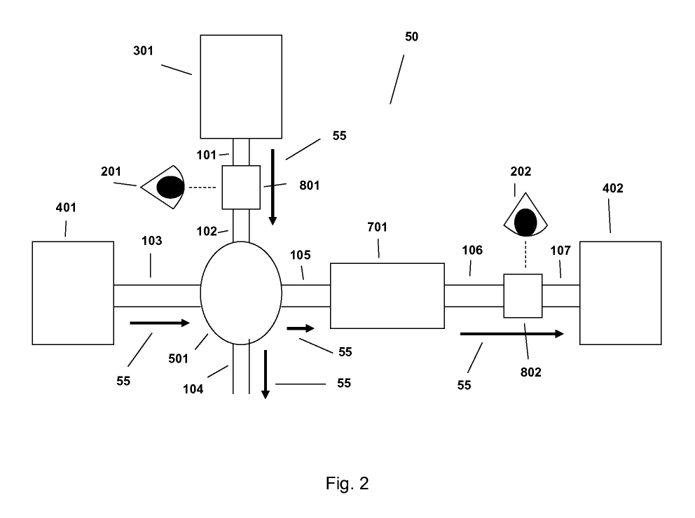

One embodiment of a device that can perform the method of the present invention is shown in FIG. 2. FIG. 2 depicts a HPLC device that can perform the method of the invention (a similar arrangement can be used for electrophoresis, gas chromatography, or other separation instruments). In FIG. 2, different detection points are used to obtain the measurement profile data from the sample and the measurement profile data from the subsamples after separation. The device in FIG. 2 is well-suited for non-destructive detection techniques like UV/Vis. In the device shown in FIG. 2, there are several different locations where measurement profile data can be acquired from the sample: the sample vials in the auto-sampler, the injection flow path before the sample injection port, the flow path of excess sample to waste after the injection port, the separation flow path before the separation channel (in this particular case, a chromatographic column). In the device in FIG. 2, the measurement profile data from the sample could be collected in continuous-flow or stopped-flow mode. In the device in FIG. 2, the measurement profile data from the sample could be collected on-line, off-line, or split-line. In the device shown in FIG. 2, there are several different locations where measurement profile data can be acquired from the subsamples obtained after separation: the separation flow path after the separation channel (in this particular case, a chromatographic column), and the fraction vials in the fraction collector. In the device in FIG. 2, the measurement profile data from the subsamples could be collected in continuous-flow or stopped-flow mode. In the device in FIG. 2, the measurement profile data from the subsamples could be collected on-line, off-line, or split-line. As mentioned previously, the detection of the measurement profile data can share common parts even though different detection points are used. Thus, the different detection points can share a common source and detector by changing the optical path. In the device in FIG. 2, a single sample injection can be used to collect both measurement profile data from the sample and from the subsamples after separation.

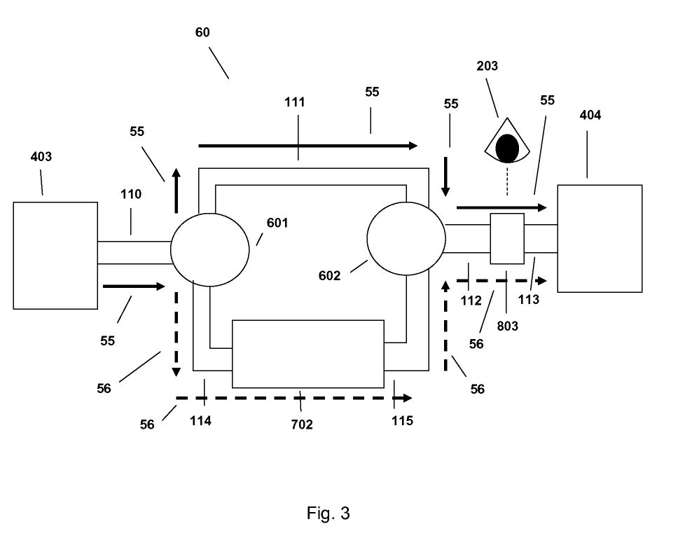

Another embodiment of a device that can perform the method of the invention is shown in FIG. 3. FIG. 3 depicts a HPLC device that can perform the method of the invention (a similar arrangement can be used for electrophoresis, gas chromatography, or other separation instruments). In FIG. 3, one detection point is used to obtain both the measurement profile data from the sample and the measurement profile data from the subsamples after separation. The device in FIG. 3 is well-suited for destructive detection techniques like MS as well as non-destructive detection techniques like UV/Vis. The device in FIG. 3 would need two injections of sample: one injection to obtain the measurement profile data of the sample and another injection to obtain the measurement profile data of the subsamples after separation. (An alternative device could use a single injection by splitting the flow at the primary valve between the two fluid paths rather than opening one fluid path and closing the other fluid path as in the present device). In the device depicted in FIG. 3, a first (primary) valve determines the fluid flow path for the sample to reach the detector. In one configuration of the primary valve, the sample bypasses the separation channel (chromatographic column) and reaches the detector, thereby generating measurement profile data for the sample. (Note: if a scout separation is desired to obtain better measurement data from the sample, the scout separation can be conducted in this fluid path). In the second configuration of the primary valve, the sample goes through the separation channel (chromatographic column) before reaching the detector, thereby generating measurement profile data for the subsamples obtained after separation. In the device depicted in FIG. 3, a synchronized secondary valve is used to ensure that the fluid flow path reaches the detector. The valves in the device could be automatically controlled or manually controlled.

As shown in the two embodiments described above, the measurement profile data from the sample and the measurement profile data from the subsamples can be collected at the same or different positions on the instrument. The measurement profile data from the sample can be collected from any appropriate location of the device including but not limited to one or more of the following: off-line at auto-sampler in the sample vial, on-line before injection loop, on-line at injection loop, on-line after injection loop, on-line before separation channel, on-line before chromatographic column, split-line prior to separation channel, split-line prior to chromatographic column, and the like. The measurement profile data from the subsamples can be collected from any appropriate location of the device including but not limited to one or more of the following: on-line after separation channel, on-line after chromatographic column, off-line after separation channel, off-line after chromatographic column, in collected fraction vials, and the like. The measurement profile data from the sample and the measurement profile data from the subsamples can be collected from the same or different injections of the sample. The measurement profile data from the sample and the measurement profile data from the subsamples can be collected during continuous-flow or stopped-flow. The measurement profile data from the sample and the measurement profile data from the subsamples can be collected on-line, off-line, or split-line. The measurement profile data from the sample and the measurement profile data from the subsamples can be collected using any flow cell, cuvette, sample vial, or fraction vial. The present invention can use any method for collecting measurement profile data from samples and measurement profile data from subsamples in sample vials and/or fraction vials.

The invention can use a multiple-stage separation to separate the sample into subsamples rather than just a single-stage separation. If desired, measurement profile data can be obtained after each stage of the separation, in which the total of the measurement profile data from each separation stage can be compared to each other as well as the measurement profile data from the sample. The invention can use any calibration technique for calibrating the devices and equipment of the invention, including the separation performance and detector performance.

The device used to conduct the method of the invention can have any parts, components, features, or the like currently used in separation devices including but not limited to one or more of the following: auto-sampler, sample tray, fraction collector, automatic operation, labor-free operation, remote control, safety alarms, temperature control of sample injection, temperature control of separation channel, temperature control of detector, Peltier cooling, parallel separation channels, and parallel chromatographic columns. Temperature control might be important to ensure that the measurement profile data from the sample and the measurement profile data from the subsamples are collected at the same (or similar) temperature, because the measurement profile data might depend upon temperature.

If a flow cell is used in the device, the flow cell might need to be able to withstand the pressure that will be applied to it during operation. Thus, if a flow cell is placed right before a chromatographic column, the flow cell might need to be able to withstand the high pressures used by the HPLC device. To ameliorate these situations in HPLC, a low-pressure chromatographic column, such as a monolithic chromatographic column, can be used. As an alternative or complement, a specialty flow cell that can withstand high pressure could be used.

For devices using optical techniques to obtain measurement profile data, one or more flow cells can be important components. Traditional flow cells in separation techniques include straight capillary flow cells, bubble flow cells, and other transverse-detected curved-wall cells, and the like that experience dependence of optical pathlength on the index of refraction of the separation solution (mobile phase). Due to the curved nature of the surface of these flow cells and the size of the optical beam diameter with respect to the flow cell curvature size, the optical path length of these flow cells depends upon the index of refraction of the separation solution (mobile phase). Since the intensity of the measurement profile data is related to the optical path length of the flow cell, the intensity of the measurement profile data depends upon the index of refraction of the separation solution (mobile phase). For isocratic HPLC methods, the mobile phase composition is kept constant over the course of the method. However, in gradient HPLC methods, the mobile phase composition is deliberately changed over the course of the method. Thus, if there is a difference in index of refraction between the different mobile phases used during a gradient HPLC method, the optical pathlength will change over the course of the method for a traditional flow cell, thereby impacting the intensity of the collected measurement profile data. As a method to minimize this problem, specialty flow cells can be used in which the effect of index of refraction of the separation solution (mobile phase) on optical pathlength is lessened compared to traditional flow cells. As an example, liquid-core waveguide flow-cells can be used. Liquid-core waveguide flow-cells operate on the principle of total internal reflection and can be used when the index of refraction of the flow cell is lower than the index of refraction of the separation solution (mobile phase) and the incident optical angle is greater than the critical angle. Among the common mobile phases used in HPLC, water often has the lowest index of refraction (the index of refraction depends upon wavelength). Thus, a liquid-core waveguide flow cell with an index of refraction below that of water (or whatever mobile phase is used that possesses the lowest index of refraction at the wavelengths of interest) at the wavelengths of interest can be used for HPLC detection. If the liquid-core waveguide flow-cell is properly designed, the effects of the index of refraction of the separation solution (mobile phase) on optical path length can be smaller than for traditional flow cells. As another example, rectangular-wall flow cells can be used. For rectangular-wall flow cells with a normal (perpendicular) incident angle for the optical beam, the effects of the index of refraction of the separation solution (mobile phase) on optical path length are smaller than for traditional flow cells. Other flow cells that exhibit less dependence of the index of refraction of the separation solution (mobile phase) on the optical path length can be used. For the purposes of this invention, all flow cells that exhibit high resistance to fluidic pressure and/or exhibit less dependence of the index of refraction of the separation solution (mobile phase) on the optical path length than traditional flow cells are referred to as specialty flow cells.

### Types of Separations

The invention can be used with any separation technique of a sample into component subsamples. In one embodiment it is the separation by a single device. Separation techniques include: chromatography, uses any type of chromatographic packing material (such as silica, polymeric, monolithic phase), uses any size of chromatographic packing material (such as five micron diameter particles, three micron diameter particles, one micron diameter particles), uses chromatographic packing material with any pore size, uses any type of chemistry on the chromatographic packing material (such as C18, C8, amino, phenyl, or any other types of chemistry), uses a packed separation column, uses an open tubular separation column, uses any length of separation column, uses any injection temperature, uses any type of separation solution, uses any type of carrier gas or carrier gases, uses any type of chromatographic coating chemistry on the separation column surface (such as polydimethyl siloxane, polyethylene glycol, or any other types of chromatographic coating chemistry that are well known to practitioners in the art and science of separations), uses any type of chiral chromatographic chemistry, uses any type of chiral modifiers, uses any type of chiral mobile phase, uses any type of chiral chemistry on the chromatographic packing material, ion mobility, gas chromatography, gas-liquid chromatography, gas-solid chromatography, gas chromatography by headspace analysis, gas chromatography by direct solution or liquid injection, gas chromatography by pyrolysis sampling, liquid chromatography, adsorption liquid chromatography, partition liquid chromatography, uses any type of pump (or pumps) in the separation (such as for liquid chromatography, electrochromatography, or the like), high performance liquid chromatography, fast liquid chromatography, ultra high pressure liquid chromatography, size exclusion chromatography (also known as gel permeation chromatography, gel filtration chromatography, and the like), ion chromatography (also known as ion exchange chromatography), super-critical fluid chromatography, electro-chromatography, uses an electric field for separation, electrophoresis, capillary electrophoresis, micellar electrokinetic capillary chromatography, isotachophoresis, isoelectric focusing, gel electrophoresis, uses any type of stationary phase, uses any type of mobile phase or mix of mobile phases, operates in any type of chromatographic mode (for example, reverse-phase, normal-phase, or any other mode types), uses isocratic mobile phase during method run, uses gradient mobile phase during method run, uses any buffers, uses any electrolytes, uses any modifiers, uses any micelles, uses multiple separation stages, uses parallel separations, uses any temperature, uses any pH, uses any pressure, uses any electric field strength, uses any pre-column derivitization, uses any post-column derivitization, uses any pre-separation derivitization, uses any post-separation derivitization, uses any pre-injection derivitization, uses any post-column splitting for separate detectors and/or fraction collection, uses any splitting for separate detectors and/or fraction collection after separation, uses any fraction collection, uses any fraction collection in which the fraction collector collects eluent based upon volume or upon elapsed time or upon detector response (for example, an on-line detector is used to detect separated subsamples and then automatically switches the fraction volume container in order to better isolate subsamples for subsequent analysis), uses any post-column mobile phase modification, uses any mobile phase modification after separation, uses any post-column mobile phase modification to assist ionization for mass spectrometry, uses any mobile phase modification to assist ionization for mass spectrometry after separation, uses any post-column mobile phase modification to change pH, uses any mobile phase modification to change pH after separation, uses any post-column mobile phase compensation to create constant mobile phase composition for post-column detection during gradient elution, uses any off-line preparatory methods (such as solid-phase extraction, centrifugation, preparatory chromatography, filtration, dialysis, or any other types of preparatory methods that are well known to practitioners in the art and science of separations) prior to the separation, uses any on-line sample pre-treatment (such as sieve, frit, trap column, guard column or any other types of pre-treatment methods that are well known to practitioners in the art and science of separations) prior to the separation, or any other characteristics (including any type of separation run under any experimental and instrumental conditions with any type of equipment and parts) not listed that are well known to practitioners in the art and science of separations.

As mentioned previously, the invention can use a multiple-stage separation to separate the sample into subsamples rather than just a single-stage separation. If desired, measurement profile data can be obtained after each stage of the separation, in which the total of the measurement profile data from each separation stage can be compared to each other as well as the measurement profile data from the sample.

### Types of Measurement Profile Data

The invention can collect any measurement profile data for comparison between samples and subsamples. Measurement profile data includes but is not limited to one or more of the following: ultraviolet-visible spectroscopy, ultraviolet-visible spectroscopy with a photo-diode array detector, ultraviolet-visible spectroscopy with any type of detector (for example, photodiode array, diode array, photomultiplier tube, charge-coupled device or any other detectors that are well known to practitioners in the art and science of measurement science or spectroscopy), ultraviolet-visible spectroscopy with any type of source (for example, tungsten lamp, Deuterium lamp, or any other sources that are well known to practitioners in the art and science of measurement science or spectroscopy), near infrared spectroscopy, ultraviolet-visible-near infrared spectroscopy, ultraviolet spectroscopy, visible spectroscopy, infrared spectroscopy, Raman spectroscopy, nuclear magnetic resonance spectroscopy, fluorescence spectroscopy, laser-induced fluorescence spectroscopy, radioactive measurement, refractive index measurement, circular dichroism, coulometry, cyclic voltammetry, mass spectrometry, mass spectrometry with any type of detector (for example, single quad detector, triple quad detector, ion trap detector, time-of-flight detector, Fourier transform ion cyclotron resonance detector, or any other detectors that are well known to practitioners in the art and science of measurement science or spectroscopy), mass spectrometry with any type of ionization (for example, electrospray ionization, atmospheric plasma chemical ionization, atmospheric pressure photoionization, inductively coupled plasma ionization, matrix assisted laser desorption ionization, or any other ionization types that are well known to practitioners in the art and science of measurement science or spectroscopy), mass spectrometry with any type of multiple iteration (for example, MS/MS spectroscopy, MS to the nth power, or the like), mass spectrometry used in positive ion mode, mass spectrometry used in negative ion mode, flame ionization detection, atomic absorption spectroscopy, atomic emission spectroscopy, inductively coupled plasma atomic emission spectroscopy, inductively coupled mass spectrometry, evaporative light scattering, light scattering, chemiluminescence detection, nitrogen chemiluminescence detection, cavity ringdown spectroscopy, any measurement technique operating in inverse detection mode, any measurement technique using any type of source, any measurement technique using any type of detector, any measurement technique using any type of non-destructive detector (i.e. the sample or any portion thereof analyzed is not destroyed during data measurement), any measurement technique collecting single-measurement-point data, any measurement technique collecting multiple-measurement-point data, any measurement technique using any type of destructive detector (i.e. the sample or any portion thereof analyzed is destroyed during data measurement), any measurement technique using an analog-to-digital converter (or converters) with a large dynamic range, or any other measurement techniques, equipment, parts, experimental parameters, and instrumental parameters not listed that are well known to practitioners in the art and science of measurement science or spectroscopy.

As an embodiment of the method of the invention, multiple detection techniques can collect measurement profile data from both the sample and the subsamples obtained after separation. As an example, a HPLC instrument with UV/Vis diode array detection and MS detection can collect both UV/Vis spectra and MS spectra from the sample and from the subsamples. Thus, the UV/Vis spectrum of the sample can be compared to the combined UV/Vis spectrum obtained from the UV/Vis spectra of the subsamples while the MS spectra of the sample can also be compared to the combined MS spectrum obtained from the MS spectra of the subsamples.

Usually, the measurement profile data obtained from the sample and the subsamples will be the same type. As an example, UV/Vis spectra from a diode array detector will be acquired from the sample and the subsamples obtained after separation. However, if desired, the measurement profile data obtained from the sample and subsamples could be of a different type, and a conversion process could be used if standards exist to predict a common measurement profile data format. Alternatively, for samples consisting of known components with standards, the mass quantity of components (and/or moles) could be calculated for comparison.

### Scout Separations

For some types of measurement profile data, components in the sample can interfere with the detection of other components. As an example, MS detection can experience ion suppression, wherein a sample component will not ionize, and therefore will not be detected, as a result of the presence of another sample component (oftentimes inorganic salts). As a consequence, an embodiment of the method of the invention comprises subjecting the sample to a scout (preparatory) separation to avoid problems such as signal suppression or the like.

Ideally, the scout separation would be relatively short and gentle so that, for example, no sample component would be excessively retained on the stationary phase and, consequently, not reach the detector and no sample component would experience any degradation and the like. Thus, the comprehensive separation step would have more separating power and/or use a different separation technique to fully resolve peaks and increase the peak capacity of the separation. For purposes of this invention, if the scout separation and comprehensive separation use the same type of separation technique and both are operating properly under the same instrumental conditions, the scout separation should elute a given sample component faster to the detector than the comprehensive separation. As an example, a scout chromatographic column has the same type of surface chemistry (example given, C18) as the comprehensive chromatographic column but has nominally less chromatographic surface area (such as by being shorter in length, or being smaller in diameter, or the like), thereby resulting in faster eluting sample components. This is in contrast to parallel separations, wherein a given sample component might elute faster on either separation method depending upon the particular nature of the given sample component and the particular nature of the separation methods. For the purposes of this invention, the scout separation could comprise a brief separation of a different technique than the comprehensive separation. As an example, if chromatography is used for the comprehensive separation, then the scout separation could be comprised of passing the sample through a membrane, subjecting the sample to dialysis, subjecting the sample to a transient CE separation (samples then pushed with pressure to the detector after transient CE), or the like. For MS detection of a sample, the scout separation could isolate the sample components from inorganic ions and/or separate the sample components slightly from each other to avoid ion suppression of the sample components. Of course, different scout separations could be conducted and the results compared to each other. Thus, multiple injections of the sample can be performed to obtain different scout separations. As an alternative or complement, different sample solutions (such as more acidic, more basic, different solvents, or the like) can be used to bring the sample to the detector for collecting sample measurement profile data under different (ionization) environments. As an alternative or complement, sample measurement profile data can be collected from different sample concentrations (such as by injecting a smaller sample volume in the mobile phase) to lessen concentration-dependent signal suppression. The sample solution from the injection can be properly mixed with the mobile phase solution by using microfluidic channels (Brownian motion) or other means. Of course, the operations can be conducted automatically or manually.

Moreover, diagnostic measurements could be acquired from the sample prior to any separation to determine if signal suppression might occur or are likely to be expected. As an example, a conductivity measurement could reveal that the sample might have a high concentration of inorganic ions, which could cause ion suppression of sample components. As an example, pH measurement could reveal that the sample pH might inhibit ionization of sample components for MS detection (or potentially impact other types of measurement profile data). Of course, measurement profile data could also be obtained from the sample before separation for comparison to the measurement profile data obtained from the sample after the scout separation and for comparison to the measurement profile data obtained from the subsamples after comprehensive separation.

Obtaining Measurement Profile Data from Samples and Subsamples

The collection of measurement profile data from a sample can be accomplished at any time relative to collecting measurement profile data from the subsamples obtained after separation (i.e. the subsample measurement profile data could be collected before the sample measurement profile data or the subsample measurement profile data could be collected after the sample measurement profile data). The measurement profile data collected from a sample can be compared to library reference measurement profile data. The comparison can possibly be done by a computer with techniques such as least squares fitting, or the like. The computer can then report the particular library reference measurement profile data that most closely match the sample measurement profile data. As an example, a UV/Vis spectrum from a sample can be compared by a computer with a least squares analysis to the UV/Vis spectra of different reference chemicals in an electronic library. Similarly, the measurement profile data collected from each of the subsamples obtained after separation can be compared to library reference measurement profile data.

Multiple measurement profile data can be collected from a sample over time to check for possible sample degradation. As an example, UV/Vis spectra can be initially acquired from a sample and can also be acquired from the same sample at a later time (such as one hour later) for comparison to check for potential sample degradation. Similarly, multiple measurement profile data can be collected from multiple separation runs of the same sample over time to check for possible sample degradation.

In some embodiments, in order to facilitate the comparison of measurement profile data collected from the sample to the measurement profile data collected from the subsamples obtained after separation, the detection response should be standardized to give similar results (ideally statistically equivalent within variation) for a reference standard (or standards). For the purposes of this invention, “standardization” refers to the processing of measurement profile data so that measurement profile data collected from the reference standard (well-behaved sample) and measurement profile data collected from the reference standard (well-behaved subsamples) after separation are similar (ideally statistically equivalent within variation). Thus, in some embodiments of the invention method, standardization is used in addition to the other types of calibration used for separation devices (such as separation performance, detector sensitivity, detector wavelength calibration, or the like). Standardization can be particularly useful for quantitative comparisons. Standardization can be particularly useful for invention method devices that collect measurement profile data from two or more instrument detection points (such as flow cells) [although, invention method devices with a single instrument detection point (such as a flow cell) could still need standardization for reasons described later]. The reference standard should be well-behaved for the separation (i.e. does not suffer degradation, reaches the detector during the run time, or the like). The reference standard could be comprised of a set of different components mixed together. Several different reference standards could be used in alternate embodiments. In yet other embodiments, for aiding in quantitative results, the reference standard should be at a concentration to give a measurement value within the linear range of the measurement type. For example, for UV/Vis measurements from a flow cell with a 1 cm path length, the standard should have an absorption value between 0.5 to 1.2 absorbance units.

For standardization of detection for proper comparison of measurement profile data collected from the sample and from the subsamples obtained after separation, one or more scaling factors can be applied to one of the collected measurement profile data to give similar results (ideally statistically equivalent within variation) to the other collected measurement profile data. The composite measurement profile data created from the individual measurement profile data collected from each of the subsamples can be multiplied by a scaling factor to give similar results (ideally statistically equivalent within variation) to the measurement profile data collected from the sample. Alternatively, the individual measurement profile data collected from each of the subsamples can each be multiplied by a proper unique scaling factor to give similar results (ideally statistically equivalent within variation) to the measurement profile data collected from the sample. Alternatively, the individual measurement profile data collected from each of the subsamples can each be multiplied by a proper unique scaling factor before creating a composite measurement profile data (which itself could also be properly scaled if needed) to give similar results (ideally statistically equivalent within variation) to the measurement profile data collected from the sample. For situations in which a single measurement profile data is collected from the subsamples [such as in the case where all subsamples are pooled in a single fraction vial (with set volume and proper mixing) and measurement profile data is collected from that fraction vial], the subsample measurement profile data can be multiplied by a scaling factor to give similar results (ideally statistically equivalent within variation) to the measurement profile data collected from the sample. The scaling factor could be determined from one or more reference standards, which, in turn, could then be applied to samples or subsamples. The scaling factor could be based on peak area and/or peak height. Of course, a scaling factor could be based on peak area and a scaling factor could be based on peak height and both could be used for analysis.

The method for standardization can vary depending upon the composition and implementation of the particular device used for the method of the invention. The measurement profile data collected from the sample and from the subsamples obtained after separation could both be collected from the same instrument detection point (such as a flow cell) (see FIG. 3). The measurement profile data collected from the sample and from the subsamples obtained after separation could be collected from different instrument detection points (such as flow cells) (see FIG. 2). In an embodiment, the measurement profile data collected from the sample could be collected either in stopped-flow mode and/or continuous-flow mode depending upon the composition and implementation of the particular device used for the method of the invention. The measurement profile data collected from the subsamples obtained after separation could be collected either in stopped-flow mode and/or continuous-flow mode depending upon the composition and implementation of the particular device used for the method of the invention. The measurement profile data collected from the sample and from the subsamples obtained after separation could both be collected with the same detector and/or source. The measurement profile data collected from the sample and from the subsamples obtained after separation could be collected with different detectors and/or sources, although this could be done in a single device. Of course, if the instrument components that are used to collect the measurement profile data from the sample and from the subsamples are distinct, then the proper standardization can be more sensitive to changes in performance of these distinct instrument components than if shared components were used instead.

The intensity of the collected measurement profile data can depend upon factors including but not limited to: flow-rate (for continuous-flow measurements), injection volume, detector scan rate. Other factors well known to practitioners in the art and science of separations, measurement science, spectroscopy, or data analysis can be evaluated to ensure proper analysis. As an example, the intensity of the collected measurement profile data might be directly related to the injection volume. As an example, the intensity of the collected measurement profile data might be inversely related to the flow rate. As an example, the intensity of the collected measurement profile data might be directly related to the scanning rate of the detector, particularly for optical measurement techniques. Thus, the device used for the present invention can keep these and other important relevant parameters constant (i.e. variation should be kept low). Of course, variation could be monitored and (automatically) corrected for to facilitate the comparison of measurement profile data. Variation could be accounted for in the scaling factor applied to the individual measurement profile data collected. Moreover, if the effect of a variable on the measurement profile data is well-known, then the scaling factor for standardization can be automatically adjusted to the proper value if the variable is changed to another set value. As an example, if the scaling factor was determined with a reference standard for continuous-flow measurement of the subsamples (with stopped-flow measurement of the sample) at a flow rate of 1 mL/minute and the effect of flow rate on the measurement profile data is known to be inversely proportional, then the scaling factor for the measurement profile data for the subsamples can be automatically doubled if the flow rate is doubled to 2 mL/minute. The automatic adjustment of scaling factor can be done for other parameters including but not limited to: injection volume and detector scan rate.

Depending on the particular type of separation being performed, some of the separation parameters might not be constant due to the nature of the separation. In capillary electrophoresis, sample components that have different migration times have different velocities. In capillary electrophoresis, the migration time is approximately inversely proportional to the electric field (i.e. a higher electric field will move the sample components to the detector faster). In contrast, for chromatography at a constant flow rate, different sample components migrating at different times have similar velocity since the separation is based upon interaction with the stationary phase. Thus, in capillary electrophoresis, the electric field should be held constant to facilitate the comparison of measurement profile data collected from the subsamples obtained after separation to the collected measurement profile data of the sample. Consequently, in capillary electrophoresis, sample components that have different migration times will have different residence times in a detector flow cell, which will consequently affect the intensity of the collected measurement profile data. For well-behaved capillary electrophoresis runs (i.e. the electroosmotic flow rate is constant, the applied electric field is constant, the effects of Joule heating are negligible, or the like), the residence time in the flow cell is directly related to the migration time (i.e. components that reach the detector flow cell early have a shorter residence time in the detector flow cell than components that reach the detector flow cell later). Thus, the intensity differences in individual collected measurement profile data caused by differences in the residence time in the detector flow cell can be accounted for by properly adjusting the unique scaling factor for the subsample collected measurement profile data, thereby facilitating proper comparison to the measurement profile data collected from the sample. In capillary electrophoresis, the scaling factor for collected measurement profile data can be divided by the migration time (time from start of run). Thus, assuming ideal conditions (i.e. constant electroosmotic flow, constant electric field, the effects of Joule heating are negligible, or the like), if component A and component B gave equal detection responses under stopped-flow conditions but component A reached the detector at 1 minute from the start of the method and component B reached the detector at 2 minutes from the start of the method, then the observed detection response of component B could be twice as great as component A since component B was in the detector flow cell for twice as long as component A. Consequently, in this case, standardization could be achieved by dividing the collected measurement profile data by the migration time to negate the effects of variable residence time in the detector flow cell.

Another factor to consider is variation in the chemical environment during the separation. As an example, HPLC can be run under isocratic conditions, meaning that the composition of the mobile phase is constant during the separation. Thus, sample components migrating at different times should have the same chemical environment. However, HPLC can also be run under gradient conditions, meaning that the composition of the mobile phase is deliberately changed over the course of the separation. Thus, sample components migrating at different times might be in different chemical environments. This difference in chemical environments can impact the collected measurement profile data in several different ways, depending upon the type of measurement profile data.

One way that differences in chemical environment can impact collected measurement profile data is through the effects on instrument separation technology performance. As an example, for UV/Vis detection of HPLC, the intensity of the collected measurement profile data can be proportional to the optical path length through the flow cell. If the mobile phases used in a gradient HPLC run possess different values of index of refraction, then the index of refraction can change as the mobile phase composition changes. Consequently, for traditional HPLC detector flow cells, such as capillary flow cells, bubble flow cells, and the like, the optical path length can change during a gradient run as a result of the changing index of refraction, thereby impacting the intensity of the collected measurement profile data. Various corrective techniques can be used to lower the effects of a changing chemical environment during separation on measurement profile data. For optical detection, specialty flow cells such as liquid-core waveguide flow cells can be used in which the effect of index of refraction of the separation solution (mobile phase) on optical path length is lower than that for traditional flow cells. As previously discussed, properly designed liquid-core waveguide flow cells can exhibit less dependence of the optical path length from the index of refraction of the separation solution (mobile phase) than traditional flow cells. Thus, the measurement profile data collected from a properly designed liquid-core waveguide flow cell will be less affected by a gradient run than a traditional flow cell. Alternatively or complementarily, standards could be used to determine scaling factors to apply to the measurement profile data. The same concentration of standard could be added to the various mobile phases used in a gradient run. Thus, the concentration of standard could be kept constant during the gradient run so that appropriate scaling factors can be determined as a function of run time during the gradient method by observing the changes in intensity of the measurement profile data collected from the standard (due to changes in index of refraction) as a function of run time during the gradient method. Alternatively, different standards with different absorption profiles (ideally, the absorption profiles do not overlap) could be added to the different mobile phases used in a gradient run. Thus, the gradient composition could be determined by measuring the ratio of the standards. Moreover, the changing optical path length during the gradient could be determined by comparing the observed signal intensity of the standards to that expected from isocratic conditions and the gradient composition at the detector, thereby enabling appropriate scaling factors to be determined as a function of run time during the gradient method. Alternatively, standards could be added to the mobile phases that do not interfere with data measurement from the sample components so that “internal” standards can be used to determine the appropriate scaling factors. Alternatively, proper baseline correction (and/or proper normalization of the baseline through a correction factor) for subsample measurement profile data collected after separation, could adequately account for changes in the optical path length (such as by trying to minimize baseline drift over the course of the gradient run). Alternatively, an inverse gradient could be run in parallel with the separation gradient such that the inverse gradient is combined post-column with the separation gradient to create constant mobile phase composition when the sample components reach the detector.

Another one of the ways that the chemical environment can impact collected measurement profile data is through the effects on the sample components (for the sample and for the subsamples obtained after separation). As an example, the UV/Vis absorption spectra of a sample component might depend upon the solvent. Thus, the absorption peak maximum (maxima) might change as the mobile phase composition changes during a gradient HPLC run. Consequently, the comparison between measurement profile data collected from the sample and from the subsamples obtained after separation might be affected. Fortunately, the effect of solvent composition on measurement profile data might be small enough in some cases to be tolerated, particularly if the user is made aware of the effect. Different approaches can be used to lessen this effect. The post-column addition of an inverse gradient can be used to maintain constant mobile phase composition at the detector during a gradient separation. This approach could minimize the impact of the chemical environment on the measurement profile data collected from subsamples, particularly if the solvent composition of the sample when measurement profile data is collected is the same as the post-column detection. As another approach, theoretical correction factors accounting for changing solvent composition could be calculated and applied to the measurement profile data collected from the subsamples to facilitate comparison to the measurement profile data collected from the same sample. As another approach, when the absorption profile peak areas of the sample components are not strongly dependent on solvent composition while their absorption peak maxima are, then the combined peak areas from the measurement profile data collected from the subsamples can be compared to the peak area of the measurement profile data from the sample. If the identities of some or all of the sample components are known, correction factors can be calculated based on standards of these sample components. Thus, by having spectra of the standard in the various solvents used to collect measurement profile data of the sample before separation and after the gradient run, calculations can be made to convert one so that it is similar to the other. Thus, there could be unique, individual correction factors for known sample components (for the sample and for the subsamples obtained after separation).

The sample components themselves could change during the separation. For well-behaved samples, the sample components in the subsamples might not change during the separation. For samples that are not well-behaved, one or more of the sample components in the subsamples could chemically change during the separation. Some of the chemical changes to sample components in the subsamples could be acceptable (particularly if there is minimal impact on the measurement profile data) such as ionization changes, tautomer ratio changes, and charge-transfer-complexation changes. Of course, the separation conditions can be adjusted to avoid these chemical changes. As an example, the pH of the sample solvent and separation solution could be adjusted so that there is not an ionization difference for the components in both the sample and in the subsamples when collecting measurement profile data. However, some of the chemical changes during separation to sample components in the subsamples could be unacceptable, particularly if there is impact on the measurement profile data (such as degradation).

Another factor to consider is partial loss of sample components during the separation. This would occur if a fraction of a sample component is retained during separation so that the fraction does not reach the detector even though the remainder of the same sample component does reach the detector. This can occur in chromatography due to the presence of active sites (as an example, unreacted silanol sites on silica particles) on the stationary phase and/or the large cross-sectional area of the stationary phase. The active sites on the stationary phase can strongly retain sample components. However, the number of free active sites on the stationary phase can be decreased through repetitive multiple reference standard (or sample) injections. Thus, multiple injections of the reference standard (or sample) can be used until steady-state measurement profile data is obtained. The large cross-sectional area of the stationary phase can result in the trapping of a fraction of the sample component (even if the sample component is only weakly retained by the column). Thus, the measurement profile data from a flow injection analysis of a reference standard (well behaved sample component) might be (slightly) more intense than the measurement profile data of the reference standard (well behaved sample component) after separation. This is one potential reason to conduct standardization tests on invention method devices with only a single instrument detection point. Ideally, if this effect does occur, it is consistent across different sample components with different retention characteristics (assuming all the sample components are well behaved). If not, a variable correction factor could be used to scale sample components with stronger retention characteristics more heavily. The effects of the large cross-sectional area of chromatography on partial loss of well behaved sample components can be tested with a reference standard comprised of a plurality of well behaved components with differing retention characteristics.

As an alternative or complement to standardization of measurement profile data, the measurement profile data collected from the sample could be normalized to the composite measurement profile data obtained from the individual measurement profile data collected from the subsamples. Thus, differences could be identified between the two measurement profile data, although the cause of the difference (such as loss of a sample component due to excessive retention or the appearance of a contaminant peak arising from the instrument) might not be as apparent as from the standardization procedure. For some applications, the process of normalizing measurement profile data instead of conducting the more labor-intensive standardization process might be acceptable. Of course, both standardization of measurement profile data and normalization of measurement profile data can be conducted separately on the same raw measurement profile data for comparison. Also, the normalization procedure could be applied to measurement profile data that has already been standardized (particularly if the standardized measurement profile data from the sample and from the total of the subsamples are in close agreement). Normalization of measurement profile data could be based on peak area or peak intensity (of course, separate comparisons can be made with each approach). Individual subsample measurement profile data could also be normalized to the sample measurement profile data for comparison.

### Comparison of Measurement Profile Data Between Samples and Subsamples

The subsamples created upon separation of the sample can each have their own measurement profile data created using the same technique (or techniques for multiple types of measurement profile data) as the sample. For the purpose of this invention, the sample measurement profile data and the subsample measurement profile data can be compared by any method. The measurement profile data collected from the subsamples can be used to create a composite measurement profile data for comparison to the collected measurement profile data of the sample. As an embodiment, a composite measurement profile data of the subsamples can be created by co-adding the individual measurement profile data from the subsamples. As an alternative or complement, the individual measurement profile data collected from the subsamples can be subtracted from the measurement profile data of the sample (i.e. the individual measurement profile data from the subsamples do not necessarily need to be co-added to create a composite measurement profile data for the subsamples depending upon the comparison method used). In one embodiment, these and other operations discussed herein can be accomplished by using a computer. In another embodiment, the sample measurement profile data and the subsample measurement profile data can be compared visually, such as by overlaying them or stacking them next to each other. In other embodiments, these can be done after treating the individual measurement profile data from the subsamples with data processing (treatment) techniques such as data smoothing, baseline correction, and other treatment techniques in order to facilitate comparison to the collected measurement profile data of the sample. As an alternative or complement, the composite measurement profile data from the subsamples can be treated with data processing techniques such as data smoothing, baseline correction and other treatment techniques in order to facilitate comparison to the collected measurement profile data of the sample. Similarly, the measurement profile data from the sample can be treated with data processing techniques such as data smoothing, baseline correction and other treatment techniques in order to facilitate comparison to the collected measurement profile data of the subsamples. As mentioned previously, scaling factors for standardization and/or normalization can be applied to the measurement profile data from the sample and/or subsamples to facilitate proper comparison. In another embodiment, the measurement profile data collected from the subsamples after separation can be collected on-line (such as for individual migrating peaks) and/or off-line (such as for individual collected fractions). Thus, one composite measurement profile data can be created from on-line measurement profile data from the subsamples and another composite measurement profile data can be created from off-line measurement profile data from the same subsamples, which have been collected in fraction vials. The composite measurement profile data from the subsamples could include or exclude the measurement profile data collected from the void volume peak or void volume fraction. The composite measurement profile data from the subsamples could either include all the individual measurement profile data collected after separation or could include only measurement profile data collected after separation in which a signal peak (or peaks) is detected (exclude measurement profile data after separation where only noise is present). The collected subsamples in fraction vials could be collected based upon a set time interval, a variable time interval, a trigger such as changing UV/Vis absorbance at an on-line detector, or any other method. In another embodiment, the void volume can be either excluded or included from the fractions of subsamples collected after separation. The creation of the composite measurement profile data from the individual measurement profile data collected from the subsamples after separation can be achieved by any other methods that are well known to practitioners in the art and science of data analysis, separations, measurement science, or spectroscopy.

As mentioned previously, for some types of measurement techniques (such as MS detection for HPLC), it might be advantageous to conduct a scout separation prior to collecting measurement profile data from the sample (in the case of MS detection after a scout separation, the slight separation of sample components could ameliorate ion suppression problems, which is particularly problematic when inorganic ions are present) for comparison to the measurement profile data from the subsamples obtained after comprehensive separation. Thus, for scout separations, a set of individual measurement profile data might be collected for the sample as opposed to a single measurement profile data. The set of individual measurement profile data from the sample (after being subjected to a scout separation) can be processed by the same methods described herein for processing individual measurement profile data from the subsamples. As an example, a composite measurement profile data of the sample obtained after a scout separation can be created by co-adding the individual measurement profile data obtained from the sample after the scout separation.

In other embodiments, the measurement profile data collected from the sample can be compared to the collected measurement profile data of the subsamples without having to directly combine the individual measurement profile data from the subsamples into a composite measurement profile data. As mentioned previously, the individual measurement profile data collected from the subsamples can be subtracted from the measurement profile data of the sample. In another embodiment, the individual measurement profile data from the subsamples can be examined individually for comparison to the measurement profile data of the sample. This embodiment could be useful for avoiding the potential loss of low intensity peaks due to the potential increased noise levels resulting from co-addition of subsample data measurements. As an example, a subsample peak from a separation with a signal-to-noise ratio (S/N) of 10 that only appears in one data measurement might not be observed after co-addition with another thousand data measurements that do not contain this peak. This method could be useful for measurement profile data which is qualitative or semi-quantitative in nature but, of course, could also be useful for quantitative measurement profile data. In a further example, MS spectra are typically qualitative or semi-quantitative. The MS spectrum (or MS spectra for samples analyzed after a scout separation) obtained from the sample could be analyzed to determine which peaks (mass-to-charge-ratio, abbreviated as m/z) are present through a (automatic) peak-picking routine. Then, each individual MS spectra obtained from the subsamples after separation could be analyzed to determine which peaks are present through a (automatic) peak-picking routine. Then, all of the peaks found in the individual MS spectra obtained from the subsamples after separation could be compared to the peaks found in the MS spectrum (or MS spectra for samples analyzed after a scout separation) obtained from the sample. Thus, if the MS spectrum (or MS spectra for samples analyzed after a scout separation) obtained from the sample has a peak that is not detected in any of the MS spectra from the subsamples, then the user could suspect that the separation failed to deliver one of the components to the detector, or a sample component suffered degradation during the separation, or some other problem occurred. Similarly, if the MS spectrum (or MS spectra for samples analyzed after a scout separation) obtained from a sample is missing a peak that is present in one or more of the individual MS spectra from the subsamples, then the user could suspect that a sample component suffered degradation during the separation, or a contaminant from a previous run reached the detector during this run, or some other problem occurred. If desired, a virtual spectrum could be created from the peaks identified in the individual measurement profile data obtained from the subsamples after separation for (visual) comparison to the measurement profile data collected from the sample.

One other embodiment comprises wherein the S/N for a peak in measurement profile data obtained after separation (comprehensive or scout) could be improved by co-adding successive spectra with this peak present. An iterative process could be used to find the optimal combinations for co-adding successive spectra in a separation (comprehensive or scout) to obtain the highest S/N for a given peak. There could be different combinations of spectra added together for the different individual peaks. The estimated peak width (in separation time) could be used as a starting point for the iterative process.

As mentioned previously, scaling factors for standardization and/or normalization can be applied to the measurement profile data from the sample and/or subsamples to facilitate proper comparison. The measurement profile data from the sample and/or the individual measurement profile data from the subsamples and/or the composite measurement profile data from the subsamples can receive other (additional) data processing treatment to facilitate proper comparison of measurement profile data for the invention method. The measurement profile data can be processed with one or more of the treatment techniques described herein. Data smoothing techniques (such as Savitzky-Golay, Gaussian, Boxcar, or any other data smoothing techniques that are well known to practitioners in the art and science of separations, measurement science, spectroscopy, data analysis, computers or the like) can be applied to the measurement profile data. Baseline correction can be applied to the measurement profile data. Measurement profile data collected from a blank (or blanks) can be subtracted from the measurement profile data collected for the invention method. Measurement profile data collected from the background can be subtracted from measurement profile data collected for the invention method. Measurement profile data collected from a blank run (or blank runs) can be subtracted from the individual measurement profile data from the subsamples and/or from the composite measurement profile data from the subsamples. As mentioned previously, the measurement profile data can be properly scaled (corrected) to account for intensity (and/or S/N) differences due to factors such as changing flow rate during on-line detection or any other factors that can cause intensity (and/or S/N) differences that are well known to practitioners in the art and science of separations, measurement science, spectroscopy, data analysis, or the like. The flow rate and/or pressure or any other factors that can cause intensity (and/or S/N) differences that are well known to practitioners in the art and science of separations, measurement science, spectroscopy, data analysis, or the like can be monitored, recorded, and used to properly scale (correct) individual measurement profile data. Empirical calculations can be used to determine appropriate scaling factors (correction factors) for the measurement profile data. Empirical scaling factors (correction factors) for the measurement profile data can be calculated by using measurement profile data collected from standards, blank runs, backgrounds, or other calibration tests that are well known to practitioners in the art and science of separations, measurement science, spectroscopy, data analysis or the like. Theoretical calculations can be used to determine appropriate scaling factors (correction factors) for the measurement profile data. Theoretical scaling factors (correction factors) for the measurement profile data can be calculated by predicting effects of known experimental and instrumental parameters such as index of refraction of mobile phase during gradient elution, flow rate, pressure on signal intensity (and/or S/N) or other parameters that can cause intensity (and/or S/N) differences that are well known to practitioners in the art and science of separations, measurement science, spectroscopy, data analysis or the like. The measurement profile data obtained from the subsamples collected in fraction vials after separation can be scaled (corrected) to properly account for the volume in the fraction vials. The measurement profile data obtained from the sample in the sample vial can be scaled (corrected) to properly account for the volume in the sample vial. The individual measurement profile data from the subsamples can be properly scaled (corrected) to account for intensity (and/or S/N) differences based upon the relative number of measurements to facilitate proper comparison to measurement profile data collected from the sample. The composite measurement profile data from the subsamples can be properly scaled (corrected) to account for intensity (and/or S/N) differences based upon the relative number of measurements to facilitate proper comparison to measurement profile data collected from the sample. The measurement profile data from the sample can be properly scaled (corrected) to account for intensity (and/or S/N) differences based upon the relative number of measurements to facilitate proper comparison to measurement profile data collected from the subsamples. The measurement profile data of the invention method can be treated by any other methods that are well known to practitioners in the art and science of data analysis, separations, measurement science, spectroscopy, or the like.

As mentioned previously, the individual measurement profile data from the subsamples can be subtracted from the measurement profile data of the sample (or vice versa: the measurement profile data from the sample can be subtracted from the individual measurement profile data of the subsamples). In another embodiment, the composite measurement profile data from the subsamples can be subtracted from the measurement profile data of the sample (or vice versa: the measurement profile data from the sample can be subtracted from the composite measurement profile data of the subsamples). These operations yield the difference between the measurement profile data. For measurement profile data comprised of a single-measurement-point, the difference in a single value is determined (for example, such as the UV/Vis absorbance at 254 nm or the intensity from ELSD). For measurement profile data comprised of multiple-measurement-points, the differences at multiple values are determined (for example, the UV/Vis absorbance from 190 to 700 nm with 2 nm resolution or the proton NMR spectra or the MS spectra). For spectral measurement profile data, a difference spectrum is determined. For well-behaved separation sample analysis, the difference (or differences across multiple values) should ideally be zero (within statistical variation). For separations that are not well-behaved, the difference (or differences across multiple values) will ideally not be zero but rather will be a deviation from zero. This, of course, depends upon the relative signal strength of the sample component (or sample components) (or contamination) that experiences a problem during the separation. For example, a problematic sample component that contributed 10% of the signal intensity in the measurement profile data from the sample might be easier to identify than if the same problematic sample component contributed only 0.1% of the signal intensity in the measurement profile data from the same sample. This, of course, also depends upon the degree of overlap between the measurement profile data from the different sample components. As an example, a problematic sample component that contributed 1% of the overall spectral peak area might be easier to identify if it did not overlap with the signal peak from another sample component than if it did overlap with the signal peak from another sample component. Depending upon the specific subtraction procedure, positive and negative deviations in the difference between measurement profile data correspond to different potential problems. If the measurement profile data from the subsamples are subtracted from the measurement profile data of the sample, then positive values in the difference could correspond to excessive retention of a sample component so that it does not reach the detector during the method run time, or sample component degradation, or insufficient retention of a sample component so that it elutes in the void volume, or another such problem. If the measurement profile data from the subsamples are subtracted from the measurement profile data of the sample, then negative values in the difference could correspond to a contaminant peak from a previous run eluting in the current run, or sample component degradation, or contamination in the separation solution, or another such problem. If a difference spectrum is obtained from the comparison of spectral measurement profile data, any signal peaks in the difference spectrum could be compared to electronic library reference spectra to try to chemically identify the problem component. Likewise, if the difference spectrum shows that the subsample measurement profile data has a more intense (significant) signal peak than the sample measurement profile data, then the difference spectrum can be compared to the individual subsample spectra to try to determine if one of the subsamples is a potential contaminant peak. The comparison of the measurement profile data serves as a balance check. The balance check can be for mass equivalence, mole equivalence and/or balance in spectral space. The procedures are well suited for quantitative comparison but, of course, can also be used for semi-quantitative or qualitative comparison. Of course, the measurement profile data from the sample and the measurement profile data from the subsamples can be compared by other methods (such as by taking the ratio of the two and investigating if the ratio is unity). The measurement profile data from the sample and the measurement profile data from the subsamples can be compared by any other methods that are well known to practitioners in the art and science of data analysis, separations, measurement science or spectroscopy.

Of course, if desired, only individual measurement profile data from the subsamples with a signal peak (or peaks) present could be subtracted from the measurement profile data of the sample (i.e. individual measurement profile data obtained after separation with only noise present is not subtracted from the measurement profile data of the sample). Of course, if desired, all individual measurement profile data obtained after separation can be subtracted from the measurement profile data of the sample. Of course, if desired, the measurement profile data obtained from the void volume peak or void volume fraction could be (or could not be) subtracted from the measurement profile data of the sample.

If a difference spectrum is obtained from the subtraction of the spectral measurement profile data, then the difference spectrum can be processed by the same data treatment techniques discussed previously for the measurement profile data. The difference spectra can be processed with one or more of the techniques described herein. Data smoothing techniques (such as Savitzky-Golay, Gaussian, Boxcar, or any other data smoothing techniques that are well known to practitioners in the art and science of separations, data analysis, measurement science, spectroscopy, computers or the like) can be applied to the difference spectrum. Baseline correction can be applied to the difference spectrum. The difference spectrum can be treated by any other methods that are well known to practitioners in the art and science of data analysis, separations, spectroscopy, measurement science, computers, or the like.

As an approach to determine if the difference between sample measurement profile data and subsample measurement profile data is significant, thresholds can be set based on factors such as estimated precision or the like. Thus, if the difference between sample and subsample measurement profile data exceeds the set threshold, then the difference can be deemed significant and further data analysis and/or corrective actions can be pursued. Similarly, if the difference between sample and subsample measurement profile data is below the set threshold, then the difference can be deemed not significant. As an example, if the estimated precision of the measurement technique used to collect measurement profile data is 5%, then a threshold of 5% could be set for comparison of measurement profile data. The threshold could be based on peak height or peak area (or both could be evaluated). This approach could be useful for quantitative and semi-quantitative measurement profile data. Other techniques such as run tests, student t-test, or the like could also be used to determine if the difference between sample measurement profile data and subsample measurement profile data is significant.

In some cases for well-behaved separation analysis, the difference in the measurement profile data might not be zero but a statistically significant positive or negative value. As an example, if the UV/Vis spectrum of a sample component is affected by solvent composition in a gradient HPLC method, the UV/Vis absorption of the sample component in the sample solvent (contribution in measurement profile data from the sample) might be different than the UV/Vis absorption of the sample component obtained after the gradient separation (contribution in measurement profile data from the subsamples). Thus, the difference spectrum of the measurement profile data might exhibit statistically significant non-zero values. However, by using analysis techniques, discrepancies in difference spectra could potentially be recognized as being a measurement artifact rather than being a problem with the separation sample analysis. For example, if there was a slight discrepancy between the absorption behavior of a sample component before and after separation (such as arising from differences in solvent composition during a gradient HPLC method), the resulting peak shape in the difference spectra might reveal that the observed signal profile is not due to a missing sample component or an additional contaminant but is rather due to measurement artifacts. For instance, if the sample component had its peak maximum shifted to 555 nm (rather than 550 nm) during the HPLC run due to changing solvent conditions, then the resulting difference spectra should show a positive signal at 550 nm and a negative signal at 555 nm. This type of signal pattern in a difference spectrum could be indicative of a shift in absorption profile of a sample component and could be used to rule against an actual problem with the separation (assuming that there were no other discrepancies). As another approach for discriminating between problems in separation versus measurement artifacts, the peak-width of the signal in the difference spectra might be indicative since compounds might have a minimum absorption peak-width (i.e. if the signal peak in the difference spectrum has a peak-width below that of the minimum peak-width for that type of measurement technique, then the signal in the difference spectrum could be identified as arising from a measurement artifact). The interpretation of the difference (spectrum) between measurement profile data from the sample and measurement profile data from the subsamples can be conducted by any other methods that are well known to practitioners in the art and science of data analysis, separations, spectroscopy, measurement science, or the like.

To facilitate separation analysis, the difference (spectrum) between the measurement profile data from the sample and the measurement profile data from the subsamples can be determined in real-time as the separation progresses. Likewise, the composite measurement profile data from the subsamples can be determined in real-time by co-adding individual measurement profile data from the subsamples (immediately) after data acquisition without having to wait until the end of the run. By using real-time analysis of the difference (spectrum) between measurement profile data, the instrument could determine if all the sample components reach the detector before the end of the method run. If so desired, the method run could be (automatically) terminated before its set end time once all the sample components reach the detector [i.e. once the difference (spectrum) between the measurement profile data is zero (within statistical variation)]. Similarly, by using real-time analysis of the difference (spectrum) between measurement profile data, the method run time could be (automatically) extended if all the sample components do not reach the detector by the end of its original set time in order to allow more time for any lagging sample component (components) to reach the detector. The difference (spectrum) between measurement profile data from the sample and measurement profile data from the subsamples can be utilized for other purposes that are well known to practitioners in the art and science of data analysis, separations, spectroscopy, measurement science or the like.

The computer controlling the device conducting the invention method (or a computer in communication with the device conducting the method) can process and display the data generated by the invention method, including in real-time if desired. The computer can process and display one or more of the following, but not limited to: the measurement profile data of the sample, the separation plot (signal intensity versus run time) (plot in 2-dimensions and/or 3-dimensions depending upon the type of measurement profile data collected), the composite measurement profile data from the subsamples, the difference (spectrum) between the measurement profile data of the sample and the measurement profile data of the subsamples, electronic library reference matches to measurement profile data. The computer can process and display other data/information from analysis with the invention method that are well known to practitioners in the art and science of data analysis, separations, spectroscopy, measurement science, computers or the like.

As an alternative or complement, the comparison of the measurement profile data can be conducted by other quantitative and/or qualitative methods to search for differences. The methods can be done by computer, visually or by hand (such as visually and the like). For quantitative comparison of measurement profile data, the composite measurement profile data from the subsamples can be compared to the measurement profile data collected from the sample [or the (individual or composite) measurement profile data from the subsamples can be subtracted from the measurement profile data of the sample (or vice versa)]. This can be done by any reasonable quantitative means such as through least-squares analysis, peak integration comparison, chemometrics (such as least squares, inverse least squares, principal component analysis, principal component regression, partial least squares, and the like) or the like. For qualitative analysis, the peaks present in the measurement profile data collected from the subsamples can be compared to the peaks present in the measurement profile data collected from the sample. This can be done by any reasonable means such as through peak-picking algorithms, visual inspection by the user, and the like. The measurement profile data from the subsamples and/or the measurement profile data from the sample can also be transformed prior to comparison by means such as first-order derivative, second-order derivative, higher-order derivative, and other transformations that are well known to practitioners in the art and science of computers, data analysis, measurement science or spectroscopy. Other known operations can be used for comparison of measurement profile data such as algorithms, mathematical operations, chemometrics, and the like. Other methods can also be used for purposes of comparing measurement profile data, including statistical data analysis (such as from replicates and/or sets, including mean, variance, or any other statistical measurements), statistical process control (six-sigma), peak lists, and the like. The comparison of the measurement profile data from the subsamples and the measurement profile data from the sample can be conducted by any other methods that are well known to practitioners in the art and science of data analysis, separations, spectroscopy, computers or measurement science. Of course, the measurement profile data from the sample can be analyzed by any methods that are well known to practitioners in the art and science of data analysis, separations, spectroscopy, computers or measurement science. Of course, the measurement profile data from the subsamples can be analyzed by any methods that are well known to practitioners in the art and science of data analysis, separations, spectroscopy, computers or measurement science.

The methods described herein for comparing subsample measurement profile data to sample measurement profile data could also be used to compare different subsample measurement profile data obtained from different sample separations, such as from parallel separations of a sample or the like. Thus, as an example, the composite subsample measurement profile data (created by combining the individual subsample measurement profile data) from a sample separation can be compared to the composite subsample measurement profile data from another separation of the same sample (or aliquot thereof). As another example, the difference spectrum between two different subsample measurement profile data (obtained from two different sample separations) could be determined. Of course, the different subsample measurement profile data could be from the same sample (such as from parallel separations or the like) or from different samples (such as from different production batches of a compound or the like).

### Determining Performance of the Separation

As mentioned previously, the comparison of measurement profile data between subsamples and the sample can identify potential problems and potential issues with a separation. Identification of these problems can help the decision to redo and/or modify and/or re-develop a separation to investigate and/or correct such problems. One or more signal peaks might be present in measurement profile data collected from a sample that is not in any of the measurement profile data from the subsamples (or vice versa). Thus, if the measurement profile data from a sample has a peak that is not detected in any of the measurement profile data from the subsamples, then the difference could indicate that the separation failed to deliver one of the sample components to the detector, a sample component suffered degradation during the separation, a sample component eluted in the void volume or void fraction, or some other problem occurred. Similarly, if the measurement profile data from a sample is missing a peak that is present in one or more of the individual measurement profile data from the subsamples, then the difference could indicate that a sample component suffered degradation during the separation, a contaminant from a previous run reached the detector during this run, the separation solution is contaminated, or some other problem occurred. One problem that could be identified is where a sample component might have been retained excessively (such as during chromatography) or migrated too slowly (such as during electrophoresis) during the method run time such that the measurement profile data collected from the subsamples would not contain a signal contribution from that sample component. Another problem that could be identified is where a sample component has insufficient retention and elutes in the void volume or void fraction during separation such that the measurement profile data collected from the subsamples would not contain a signal contribution from that sample component. Another problem that could be identified is where a sample component might have been (partially or fully) degraded during separation. Another problem that could be identified is where the sample separation into subsamples might have peak-carryover from a previous separation. Yet another problem the present invention could identify is where the sample separation into subsamples might have contamination from the separation solution, mobile phase, electrolyte, buffer solution, or carrier gas used in the separation. Obviously, this list of problems identified is only a sampling. The present invention can identify the difference between the measurement profile data of the sample and the measurement profile data of the subsamples for the purpose of qualitatively and/or quantitatively analyzing the separation.

A computer can (automatically once programmed) examine the difference between the measurement profile data of the sample and the measurement profile data of the subsamples to determine if the difference could be caused by a problem in the separation or if the difference is instead due to measurement artifacts (which were discussed previously) (of course, the user could conduct this determination as well). Upon identifying any difference between the measurement profile data of the sample and the measurement profile data of the subsamples that could result from potential problems in the separation, the computer can (automatically) conduct an investigation (of course, the user could conduct the investigation as well). As an example, the computer could (automatically) re-run the sample separation (multiple times if needed or desired) to ensure that the difference between measurement profile data is reproducible. As another example, the computer could (automatically) run a blank (including different blanks such as no injection blank or solvent injection without sample blank) to ensure that the device is not contaminated and/or does not have peak-carryover. As another example, the computer could (automatically) run a reference standard to ensure that the device is operating properly. As another example, the computer could (automatically) re-run the sample after modifying the separation conditions such as increasing the time of the sample separation, increasing the temperature, decreasing the injection volume, and/or changing other separation parameters. As another example, the computer could (automatically) re-run the sample with a different separation (or separations) such as with a different chromatographic column (which is relatively simple for devices capable of parallel chromatography) and/or with different mobile phases and/or changing any other separation conditions and parameters. Of course, the exact difference between the measurement profile data of the sample and the measurement profile data of the subsamples can be used to decide which investigative actions to pursue. As an example, if the measurement profile data from the sample has an extra peak that is not present in any of the measurement profile data from the subsamples, then the computer could (automatically) re-run the sample with a longer separation time to check for any late-eluting sample components rather than running blanks to look for contamination, which would be more of a concern if the measurement profile data from the sample was missing a peak that was present in one or more of the measurement profile data from the subsamples. The computer could (automatically) notify the user of a potential problem with a separation. The computer could (automatically) generate reports about any separation with a potential problem (as well as generating reports for all sample separations performed if desired). Obviously, this list of investigative actions is only a sampling. The present invention can have the computer (automatically) and/or user conduct any investigative action to determine the cause of the difference between the measurement profile data of the sample and the measurement profile data of the subsamples.

### Use of Computer to Make Comparisons and Other Functions

The method and analysis of the present invention can be controlled and/or performed by one or more computers. As mentioned previously, the analysis of measurement profile data could be performed by the computer controlling the device and/or another computer that the data is transferred to either by network (physically connected or wireless) or data storage device. The computer can perform a number of functions including, but not limited to, one or more of the following: facilitates user operation of device, records sample or subsample measurement profile data, processes sample or subsample measurement profile data, analyzes measurement profile data, determines if sample separation has a potential problem or potential issue, determines if separation did not adequately analyze the sample, alerts operator to any potential issue or potential problem, controls automated sample analysis, monitors and/or records experimental and/or instrumental parameters (pressure, flow rate, electric field strength, temperature, pH, mobile phase composition, or any other parameters that are well known to practitioners in the art and science of separations, measurement science, spectroscopy, data analysis), alerts operator if experimental or instrumental parameters deviate from expected values, automatically shuts down sample separation or device in event of a potential safety problem, conducts automated calibration, controls separation and detection according to set methods, operates a fraction collector, applies data smoothing techniques (such as Savitzky-Golay, Gaussian, Boxcar, or any other data smoothing techniques) to measurement profile data, applies baseline correction to measurement profile data, subtracts measurement profile data from a blank run from sample or subsample measurement profile data, subtracts background measurement profile data from sample or subsample measurement profile data, calculates derivatives of measurement profile data (including first-order derivative, second-order derivative, and higher-order derivatives), creates a composite measurement profile data from the individual measurement profile data of the subsamples by co-adding the subsample measurement profile data (including after data smoothing techniques, baseline correction, and other data treatment techniques), properly scales the measurement profile data to properly account for intensity (and/or S/N) differences due to factors such as changing flow rate and/or migration time during on-line detection or any other factors that can cause intensity (and/or S/N) differences, monitors and records factors affecting intensity (and/or S/N) in measurement profile data including flow rate and/or pressure and/or electric field during on-line detection [or any other factors that can cause intensity (and/or S/N) differences], co-adds neighboring individual measurement profile data collected after separation to improve S/N when searching for signal peaks, identifies void volume peak or collected void volume fraction, calculates retention times of signal peaks, integrates signal peaks, calculates relative integral values of signal peaks from subsamples after separation, uses peak picking techniques to facilitate analysis, uses peak shape analysis to identify and analyze overlapping peaks, includes measurement profile data from void volume in composite measurement profile data of subsamples created from individual measurement profile data collected after separation, excludes measurement profile data from void volume in composite measurement profile data of subsamples created from individual measurement profile data collected after separation, determines chemical identity of sample peaks based upon retention time and/or measurement profile data, compares measurement profile data from sample or subsamples or difference spectra to electronic library reference measurement profile data using techniques such as least squares or other techniques, properly scales measurement profile data collected from sample to measurement profile data from the subsamples collected after separation for proper comparison, properly scales measurement profile data collected from sample to composite measurement profile data of the subsamples created from individual measurement profile data of the subsamples collected after separation for proper comparison, determines scaling factor for standardization of sample and subsample measurement profile data from reference standard (or reference standards), properly scales measurement profile data from sample, properly scales individual measurement profile data from subsamples, properly scales composite measurement profile data from subsamples, applies individual scaling factors to individual measurement profile data for proper comparison, automatically adjusts scaling factor to account for (deliberate or unintentional) changes in separation conditions (including but not limited to flow rate, injection volume, detector scanning rate), uses empirical calculations to determine appropriate scaling factors to use for proper comparison of measurement profile data, uses theoretical calculations to determine appropriate scaling factors to use for proper comparison of measurement profile data, uses both empirical calculations and theoretical calculations to determine appropriate scaling factors to use for proper comparison of measurement profile data, calculates theoretical scaling factors for proper comparison of measurement profile data by predicting effects of known experimental and instrumental parameters (such as index of refraction of mobile phase during gradient elution, flow rate, pressure or other parameters) on signal intensity (and/or S/N), calculates empirical scaling factors by using measurement profile data collected from standards, blank runs, backgrounds, or other calibration tests, calculates scaling factors by using a standard (or standards) present at constant levels in the separation solution, uses background measurement profile data to determine scaling factor for sample or subsample measurement profile data, uses a blank and/or blank run to determine scaling factor for sample or subsample measurement profile data, properly scales measurement profile data to account for intensity (and/or S/N) differences based upon the relative number of measurements to facilitate proper comparison of measurement profile data, properly scales measurement profile data to account for intensity (and/or S/N) differences arising from different flow-rates and/or migration times and/or residence times in the detector flow cell, properly scales measurement profile data to account for the sample injection volume, properly scales measurement profile data to account for the volume of sample or subsample, properly scales measurement profile data to account for differences in detector response (including but not limited to source intensities, flow cell path-lengths and detector sensitivities), normalizes the measurement profile data from the sample to the measurement profile data from the subsamples (or vice versa), normalizes the measurement profile data from the sample to the composite measurement profile data from the subsamples (or vice versa), determines the difference between the measurement profile data from the sample and the measurement profile data from the subsamples, determines the difference spectrum between the measurement profile data from the sample and the measurement profile data from the subsamples, uses algorithms, chemometrics (such as least squares, inverse least squares, principal component analysis, principal component regression, partial least squares, and the like), or other mathematical operations to compare the measurement profile data from the sample to the measurement profile data from the subsamples, determines quantitative differences between the measurement profile data, determines qualitative differences between the measurement profile data, compares peak lists between measurement profile data, determines if difference between measurement profile data is due to a potential problem or measurement artifacts, determines if extra signal peak (or signal peaks) is present between measurement profile data, determines if a sample component might have been excessively retained during sample separation, determines if a sample component might not have been sufficiently retained and eluted in the void volume during separation, determines if a sample component might have been degraded during separation, determines if the sample separation has peak-carryover from a previous separation, determines if the sample separation has contamination from the separation solution, automatically conducts investigations into possible causes of potential problems with separation, automatically re-analyzes sample with a potential problem to try to achieve valid separation analysis, automatically re-runs a sample that has a potential problem for proper analysis, automatically runs a reference standard to ensure proper operation of the device, automatically changes the parameters of the separation and re-runs the sample under the adjusted separation conditions if a potential problem is suspected, automatically runs another set method to analyze a sample if the previous set method fails to properly analyze the sample, uses statistics (possibly from replicates) including mean, variance or any other statistical measurements, uses statistical process control to check for potential problems, automatically re-analyzes sample over time to check for degradation, display data, generates reports, or the like or any other functions not listed that are well known to practitioners in the art and science of separations, data analysis, computers, separations or measurement science.

### DETAILED DESCRIPTION OF THE DRAWINGS

Now referring to the drawings. FIG. 1a depicts a flow chart for one embodiment of the present invention. In the method of the invention depicted, a user starting with a sample that is to be analyzed takes a sample measurement profile data (MPD) 1 from the sample. The sample then is subjected to a separation technique 6 which separates the sample into one or more subsamples 2. At least one of the subsamples, but in some embodiments all of the subsamples 2, are subjected to a measurement to obtain MPD from the desired subsamples 3.

In FIG. 1b there is a more detailed flow chart of the present invention with additional steps in the process. In this view the MPD from the sample 1 and the MPD from the subsamples 3 are compared 4. This is individual comparison or by any of the techniques listed or contemplated herein. The differences, if any, between the MPD's 4 are then used to determine the performance of the separation 5. Accordingly, if the separation has problems discovered in the performance of separation 5 step then some or all of the other steps can be repeated till the level of accuracy and efficiency needed is achieved.

FIG. 2 depicts a HPLC device 50 capable of conducting an embodiment of the invention method. The solid arrows 55 indicate the fluid flow path as a separation and MPD of the invention is performed. For the analysis method, measurement profile data has to be obtained from both the sample and from the subsamples after separation. Sample measurement profile data is obtained at flow cell 801 with UV/Vis detection location 201. Subsample measurement profile data is obtained at flow cell 802 with UV/Vis detection location 202. Each individual flow cell (801 and 802) could either be a traditional flow cell or a specialty flow cell. The HPLC device 50 could use a single source and detector by switching the optical path for detection and/or could use different equipment to collect the measurement profile data. For the analysis, one sample injection can be used.

Auto-sampler 301 injects the sample through piping 101 into the flow cell 801. After collecting sample measurement profile data in flow cell 801, the sample goes through piping 102 to the sample injector port 501 for subsequent separation. Any excess sample can overflow through piping 104 to a waste location. The UV/Vis spectrum of the sample can be obtained either in stopped-flow mode or continuous-flow mode at flow cell 801. The HPLC pumps in 401 push mobile phase through piping 103 to the sample injector port 501. After loading the sample into the sample injector port 501, the sample can be injected with mobile phase from piping 103 into the piping 105 leading to the chromatographic column 701. The sample is then separated into subsamples and flows out of chromatographic column 701 and into piping 106, which transports the subsamples into flow cell 802. At flow cell 802, measurement profile data of the subsamples are obtained. The subsample UV/Vis spectra can be obtained either in stopped-flow mode or continuous-flow mode. The subsamples pass through flow cell 802, pass through piping 107 to the remainder of the HPLC device 402, which could comprise MS detection, fraction collection, waste, or the like as desired.

In addition to the shown device 50 detection locations, other device locations can be used to collect measurement profile data by changing device parts. As an alternative or complement to the transfer piping between the auto-sampler 301 and the sample injector port 501, sample measurement profile data can be obtained at the auto-sampler 301 (such as in a sample vial), the piping 104 if excess sample is (deliberately) injected (with a flow cell), or piping 105 (with a flow cell). As an alternative or complement to the transfer piping between the chromatographic column 701 and the HPLC device remainder 402, subsample measurement profile data can be obtained at the HPLC device 50 remainder 402 (such as in fraction vials).

FIG. 3 depicts a HPLC device 60 capable of conducting an embodiment of the invention method. Both the sample measurement profile data and the subsample measurement profile data (UV/Vis) are obtained at flow cell 803 with UV/Vis detection location 203. The flow cell 803 could either be a traditional flow cell or a specialty flow cell. The measurement profile data could be collected in either continuous-flow or stopped-flow mode. For the analysis, two sample injections can be made: one injection for collecting sample measurement profile data and one injection for collecting subsample measurement profile data. The solid arrows 55 depict the flow path used to collect the sample measurement profile data. The dashed arrows 56 depict the flow path used to collect the subsample measurement profile data. The order of the injections is not critical. For this example, the injection for collecting sample measurement profile data will be described first.

HPLC device remainder 403 injects an aliquot of sample through piping 110 to 2-way valve 601, which (automatically) directs the sample to piping 111. The sample passes through piping 111 to 2-way valve 602, which (automatically) directs the sample to piping 112. The sample passes through piping 112 into flow cell 803, where sample measurement profile data is obtained. After obtaining sample measurement profile data in flow cell 803, the sample passes through piping 113 to the HPLC device remainder 404, which could comprise MS detection, fraction collection, waste, or the like.

After the analysis of the first sample injection is complete, a second sample injection is made for obtaining subsample measurement profile data. HPLC device remainder 403 injects a second aliquot of sample through piping 110 to 2-way valve 601, which (automatically) directs the sample to piping 114. The sample passes through piping 114 to the chromatographic column 702, in which the sample is separated into subsamples. After separation, the subsamples pass through piping 115 to 2-way valve 602, which (automatically) directs the subsamples to piping 112. The subsamples pass through piping 112 into flow cell 803, where subsample measurement profile data is obtained by UV/Vis detection location 203. After obtaining subsample measurement profile data in flow cell 803, the subsamples pass through piping 113 to the HPLC device remainder 404, which could comprise of MS detection, fraction collection, waste, or the like.

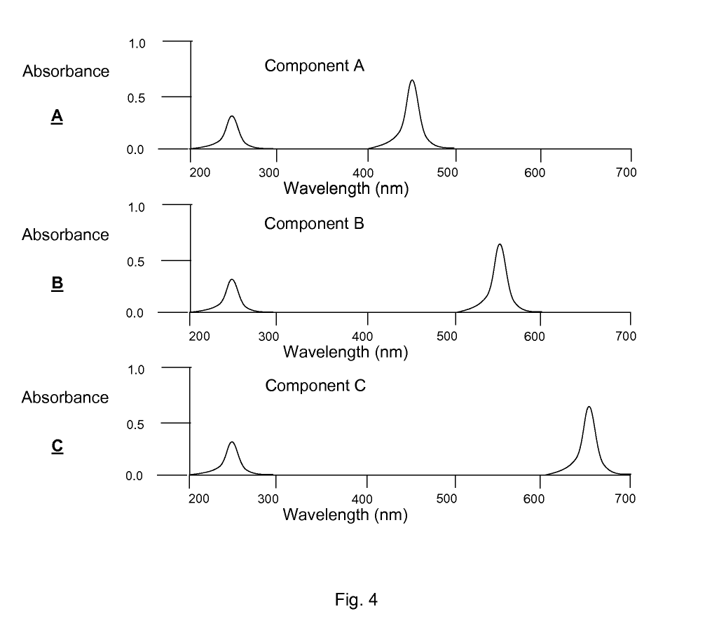

FIG. 4 depicts example UV/Vis absorbance spectra for sample components A, B, and C in example #1. The UV/Vis spectra plot absorbance as a function of wavelength in nanometers (nm). FIG. 4a shows that component A has two UV/Vis absorbance peaks, with one peak at 250 nm and the other peak at 450 nm. FIG. 4b shows that component B has two UV/Vis absorbance peaks, with one peak at 250 nm and the other peak at 550 nm. FIG. 4c shows that component C has two UV/Vis absorbance peaks, with one peak at 250 nm and the other peak at 650 nm.

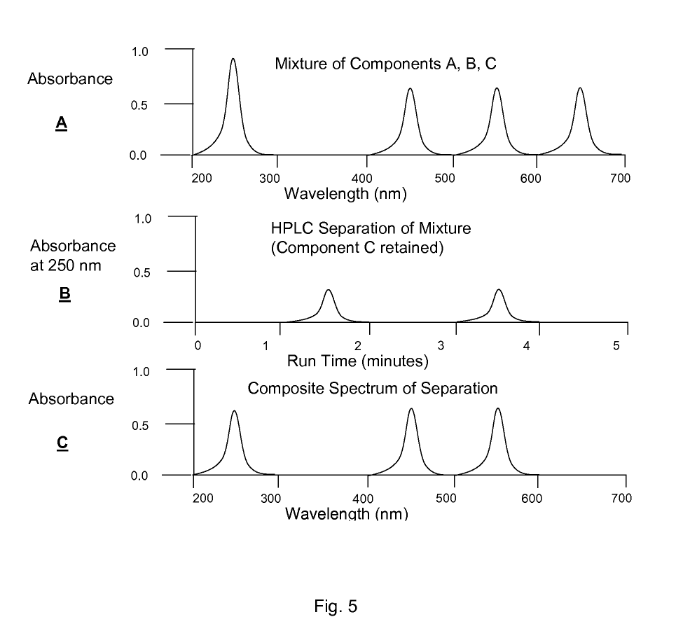

FIG. 5 depicts the experimental results for the HPLC-UV/Vis analysis of the sample mixture from example #1. FIG. 5A is the UV/Vis spectrum (plot of absorbance as a function of wavelength in nm) of the sample mixture of sample components A, B, and C, with absorbance peaks at 250, 450, 550, and 650 nm. FIG. 5b is the chromatogram from the separation of the sample mixture, showing absorbance at 250 nm as a function of run time in minutes. The chromatogram in FIG. 5b shows one peak at 1.5 minutes (from sample component A) and another peak at 3.5 minutes (from sample component B). Sample component C does not elute during the method run time. FIG. 5c is the composite UV/Vis spectrum from the subsamples (plot of absorbance as a function of wavelength in nm) created by co-adding the individual subsample UV/Vis spectra obtained after the sample separation. FIG. 5c shows absorbance peaks at 250, 450, and 550 nm.

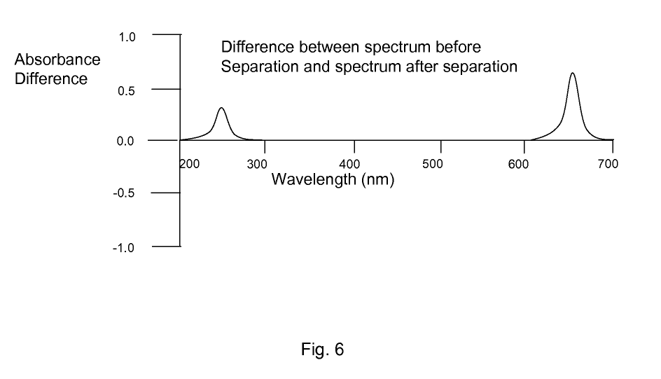

FIG. 6 depicts the difference UV/Vis spectrum from example #1 obtained by subtracting the composite subsample UV/Vis spectrum (depicted in FIG. 5c) from the sample UV/Vis spectrum (depicted in FIG. 5a). The difference spectrum plots absorbance difference as a function of wavelength in nm. The difference spectrum shows two positive peaks at 250 nm and 650 nm. The difference spectrum matches the UV/Vis spectrum of sample component C (depicted in FIG. 4c), which did not elute from the chromatographic column during the separation run time (depicted in FIG. 5b).

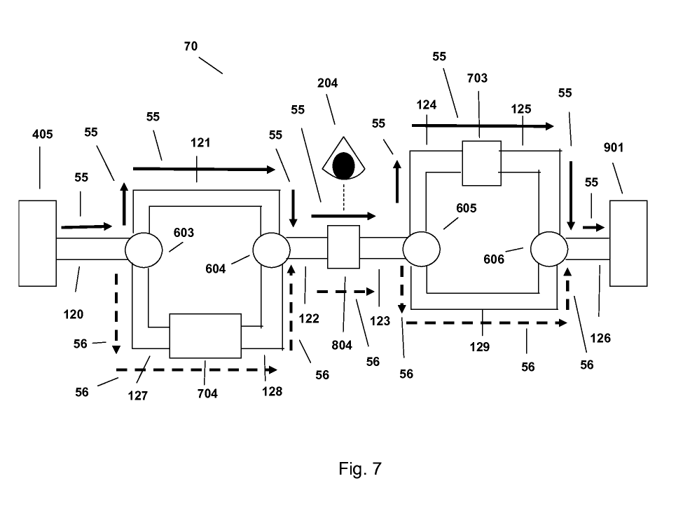

FIG. 7 depicts a HPLC-UV/Vis-MS device 70 capable of conducting an embodiment of the invention method. The device is described in example #2. In this example, both UV/Vis spectra and MS spectra are collected for the sample and subsamples. Both the sample UV/Vis spectrum and the subsample UV/Vis spectra are obtained at flow cell 804 with UV/Vis detection location 204. The flow cell 804 could either be a traditional flow cell or a specialty flow cell. Both the MS sample spectra and the MS subsample spectra are obtained at MS detector 901. To avoid potential ion suppression of the sample during MS detection, the sample is subjected to a scout separation on the short chromatographic column 703 before reaching MS detector 901. For the analysis, two sample injections can be made: one injection for collecting sample measurement profile data and one injection for collecting subsample measurement profile data. The solid arrows 55 depict the flow path used to collect the sample measurement profile data. The dashed arrows 56 depict the flow path used to collect the subsample measurement profile data. The order of the injections is not critical. For this example, the injection for collecting sample measurement profile data will be described first.

HPLC device remainder 405 injects an aliquot of sample through piping 120 to 2-way valve 603, which (automatically) directs the sample to piping 121. The sample passes through piping 121 to 2-way valve 604, which (automatically) directs the sample to piping 122. The sample passes through piping 122 into flow cell 804, where sample measurement profile data is obtained by UV/Vis detection location 204. After obtaining sample measurement profile data in flow cell 804, the sample passes through piping 123 to 2-way valve 605, which (automatically) directs the sample to piping 124. The sample passes through piping 124 to the short chromatographic column 703, in which the sample is subjected to a scout separation. After the scout separation, the sample passes through piping 125 to 2-way valve 606, which (automatically) directs the sample to piping 126. The sample passes through piping 126 to MS detector 901, where sample measurement profile data is obtained.

After the analysis of the first sample injection is complete, a second sample injection is made for obtaining subsample measurement profile data. HPLC device remainder 405 injects a second aliquot of sample through piping 120 to 2-way valve 603, which (automatically) directs the sample to piping 127. The sample passes through piping 127 to the chromatographic column 704, in which the sample is separated into subsamples. After separation, the subsamples pass through piping 128 to 2-way valve 604, which (automatically) directs the subsamples to piping 122. The subsamples pass through piping 122 into flow cell 804, where subsample measurement profile data is obtained by UV/Vis detection location 204. After obtaining subsample measurement profile data in flow cell 804, the subsamples pass through piping 123 to 2-way valve 605, which (automatically) directs the subsamples to piping 129. The subsamples pass through piping 129 to 2-way valve 606, which (automatically) directs the subsamples to piping 126. The subsamples pass through piping 126 to MS detector 901, where subsample measurement profile data is obtained.

In addition to the shown device detection locations, other device locations can be used to collect measurement profile data by changing device parts. As an alternative or complement to the flow cell between 2-way valve 604 and 2-way valve 605 for UV/Vis detection, sample UV/Vis spectra could be obtained between the short chromatographic column 703 and the MS detector 901, in which the UV/Vis sample spectra would be obtained after subjecting the sample to scout separation.

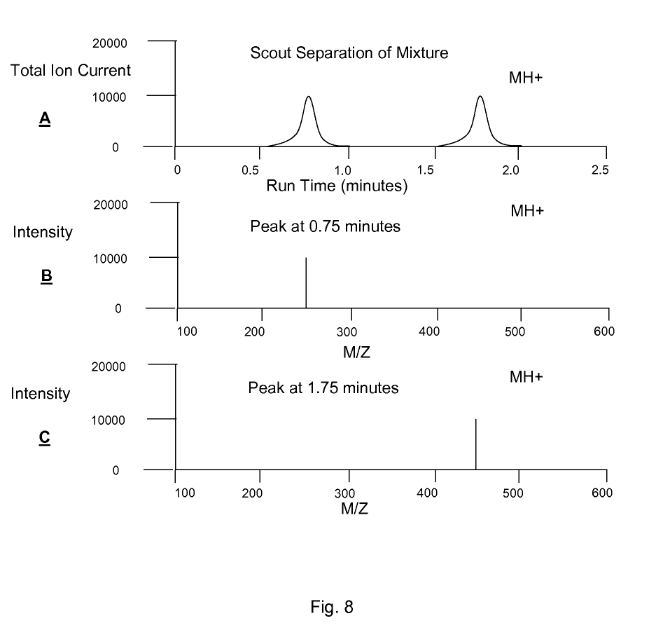

FIG. 8 depicts the experimental results for the LC-MS analysis from the scout separation of the sample in example #2. In example #2, the MS detector uses electrospray ionization (ESI) in positive ion mode (denoted by MH+ in plots). FIG. 8a is the chromatogram from the scout separation of the sample, showing total ion current (TIC) intensity as a function of run time in minutes. The chromatogram in FIG. 8a shows one peak at 0.75 minutes (from one sample component) and another peak at 1.75 minutes (from the other sample component). FIG. 8b is the MS spectrum from the peak maximum of the first peak in the chromatogram (at 0.75 minutes), showing intensity as a function of mass-to-charge ratio (m/z). The MS spectrum in FIG. 8b depicts a peak at 251 m/z. FIG. 8c is the MS spectrum from the peak maximum of the second peak in the chromatogram (at 1.75 minutes), showing intensity as a function of m/z. The MS spectrum in FIG. 8c depicts a peak at 451 m/z.

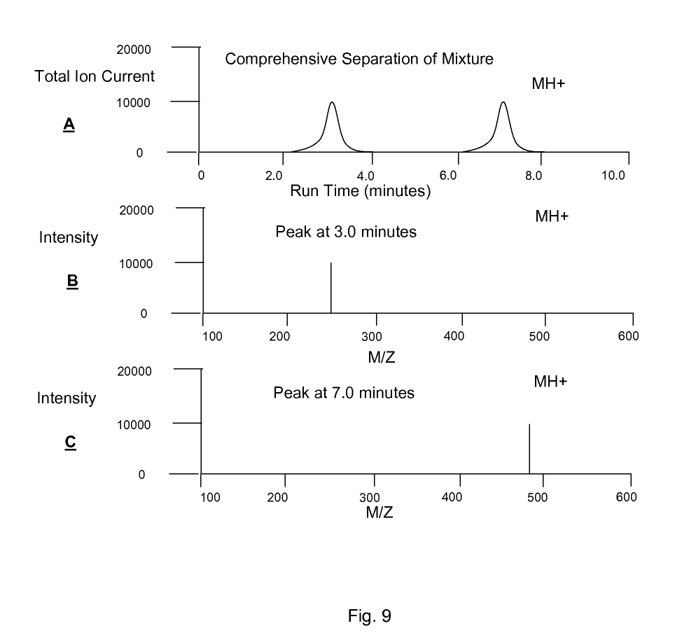

FIG. 9 depicts the experimental results for the LC-MS analysis from the comprehensive separation of the sample in example #2. In example #2, the MS detector uses ESI in positive ion mode (denoted by MH+ in plots). FIG. 9a is the chromatogram from the comprehensive separation of the sample, showing TIC intensity as a function of run time in minutes. The chromatogram in FIG. 9a shows one peak at 3.00 minutes (from one sample component) and another peak at 7.00 minutes (from the other sample component). FIG. 9b is the MS spectrum from the peak maximum of the first peak in the chromatogram (at 3.00 minutes), showing intensity as a function of m/z. The MS spectrum in FIG. 9b depicts a peak at 251 m/z. FIG. 9c is the MS spectrum from the peak maximum of the second peak in the chromatogram (at 7.00 minutes), showing intensity as a function of m/z. The MS spectrum in FIG. 9c depicts a peak at 483 m/z.

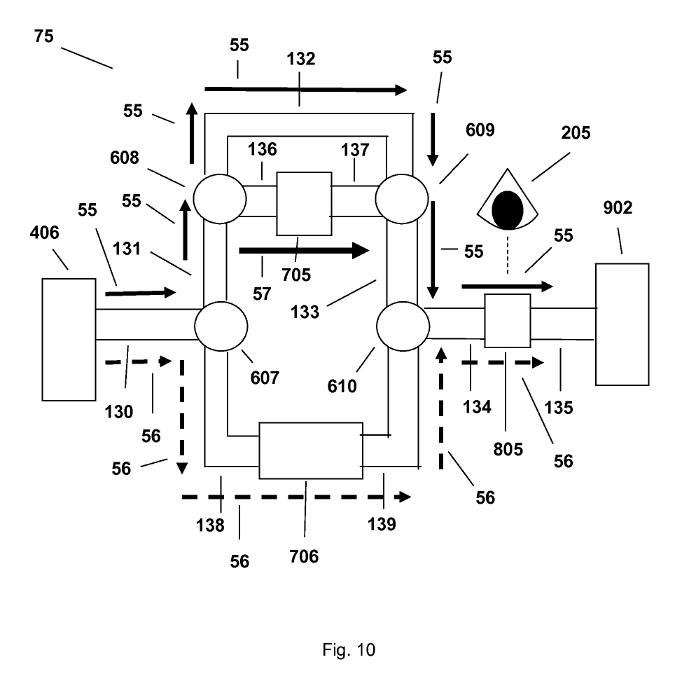

FIG. 10 depicts a HPLC device 75 capable of conducting an embodiment of the invention method. The device 75 is described in example #2. For this analysis method, measurement profile data is obtained from the sample without any scout separation, from the sample after scout separation (hereafter in this figure description referred to as “scout sample”), and from the subsamples after separation. In this example, both UV/Vis spectra and MS spectra are obtained for the sample, scout sample, and subsamples. The sample UV/Vis spectrum, the scout sample UV/Vis spectra, and the subsample UV/Vis spectra are obtained at flow cell 805 and with UV/Vis detection location 205. The flow cell 805 could either be a traditional flow cell or a specialty flow cell. The sample MS spectrum, the scout sample MS spectra, and the subsample MS spectra are obtained at MS detector 902. To avoid potential ion suppression of the sample during MS detection, the scout sample is subjected to a scout separation on the short chromatographic column 705 before reaching MS detector 902.

For the analysis, three sample injections can be made: one injection for collecting sample measurement profile data, one injection for collecting scout sample measurement profile data, and one injection for collecting subsample measurement profile data. The solid arrows 55 depict the flow path used to collect the sample measurement profile data. The solid arrow 55 with the solid arrow 57 depict the flow path used to collect the scout sample measurement profile data. The dashed arrows 56 depict the flow path used to collect the subsample measurement profile data. The order of the injections is not critical. For this example, the injection for collecting sample measurement profile data will be described first, then the injection for collecting scout sample measurement profile data will be described, and then the injection for collecting subsample measurement profile data will be described last.

HPLC device remainder 406 injects an aliquot of sample through piping 130 to 2-way valve 607, which (automatically) directs the sample to piping 131. The sample passes through piping 131 to 2-way valve 608, which (automatically) directs the sample to piping 132. The sample passes through piping 132 to 2-way valve 609, which (automatically) directs the sample to piping 133. The sample passes through piping 133 to 2-way valve 610, which (automatically) directs the sample to piping 134. The sample passes through piping 134 into flow cell 805, where sample measurement profile data is obtained by UV/Vis detection location 205. After obtaining sample UV/Vis spectrum in flow cell 805, the sample passes through piping 135 to MS detector 902, where sample measurement profile data is obtained.

After the analysis of the first sample injection is complete, a second sample injection is made for obtaining scout sample measurement profile data. HPLC device remainder 406 injects a second aliquot of sample through piping 130 to 2-way valve 607, which (automatically) directs the sample to piping 131. The sample passes through piping 131 to 2-way valve 608, which (automatically) directs the sample to piping 136. The sample passes through piping 136 to the short chromatographic column 705, in which the sample is subjected to a scout separation. After the scout separation, the scout sample passes through piping 137 to 2-way valve 609, which (automatically) directs the scout sample to piping 133. The scout sample passes through piping 133 to 2-way valve 610, which (automatically) directs the scout sample to piping 134. The scout sample passes through piping 134 into flow cell 805, where scout sample measurement profile data is obtained by UV/Vis detection location 205. After obtaining scout sample UV/Vis spectra in flow cell 805, the scout sample passes through piping 135 to MS detector 902, where scout sample measurement profile data is obtained.

After the analysis of the second sample injection is complete, a third sample injection is made for obtaining subsample measurement profile data. HPLC device remainder 406 injects a third aliquot of sample through piping 130 to 2-way valve 607, which (automatically) directs the sample to piping 138. The sample passes through piping 138 to the chromatographic column 706, in which the sample is separated into subsamples. After separation, the subsamples pass through piping 139 to 2-way valve 610, which (automatically) directs the subsamples to piping 134. The subsamples pass through piping 134 into flow cell 805, where subsample measurement profile data is obtained by UV/Vis detection location 205. After obtaining subsample UV/Vis spectra in flow cell 805, the subsamples pass through piping 135 to MS detector 902, where subsample measurement profile data is obtained.

Diagnostic measurements (such as conductivity and/or pH) could be collected from the sample to determine if ion suppression is a potential problem for MS detection. Depending upon the results of the diagnostic measurement from the sample, sample measurement profile data could be collected from only the sample without scout separation or from only the sample after scout separation or from both approaches. As an example, if conductivity measurements show that the sample is highly conductive, perhaps sample measurement profile data would only be obtained after scout separation since ion suppression might be likely if the sample was directly injected for MS detection.

### FIGURE GLOSSARY

Description of parts used in figures:
50: device
55: fluid flow direction
56: fluid flow direction
57: fluid flow direction
60: device
65: device
70: device
100 series (100-199): HPLC fluid transport piping or tubing
200 series (200-299): UV/Vis detection location with flow cell in sight path (UV/Vis source and detector not shown) (symbolic eye symbol is used to depict UV/Vis measurement and does not necessarily mean human observer is present looking at flow cell)
300 series (300-399): auto-sampler
400 series (400-499): remainder of HPLC instrument not shown
500 series (500-599): HPLC sample injector port
600 series (600-699): 2-way valve (automated)
700 series (700-799): chromatographic column
800 series (800-899): specialty or conventional HPLC flow cell
900 series (900-999): MS detector (including ionization) for HPLC

### EXAMPLES

### Example 1

### HPLC-UV/Vis of Samples

A HPLC instrument with UV/Vis diode-array detection uses the following method to analyze samples: obtain a UV/Vis spectrum from the sample prior to chromatographic separation, subject the sample to a chromatographic separation, obtain a series of on-line continuous-flow UV/Vis spectra from the subsamples after the chromatographic separation, compare the combined UV/Vis spectra from the subsamples measured after chromatographic separation to the UV/Vis spectrum of the sample obtained before chromatographic separation. In this particular example, the HPLC instrument collects both the pre-separation and post-separation UV/Vis spectra from one flow cell by switching flow paths (see FIG. 3). In this particular example, the HPLC instrument uses a liquid-core waveguide as the flow cell for UV/Vis measurements to minimize effects of index of refraction on optical pathlength. In this particular example, the flow cell temperature is set to 25 C during the analysis. In this particular example, the instrument collects the UV/Vis spectrum from the sample before chromatographic separation by injecting a set volume of the sample into the flow cell at the same flow rate as the chromatographic separation. In this particular example, a second sample injection of the same volume is subjected to chromatographic separation.

For the HPLC method in this example, UV/Vis spectra consist of measurement from 200 nm to 700 nm with a resolution of 2 nm. The HPLC method uses a gradient run with an 95% water/5% acetonitrile mobile phase with a linear ramp to 95% acetonitrile/5% water mobile phase over 4 minutes, with a 1 minute hold-time before the analysis method is complete. The HPLC uses a microbore C18 column.

In this example, a “blind” operator analyzes an “unknown” mixture. The sample mixture consists of three dyes, labeled as Component A, Component B, and Component C. The sample mixture solvent is 95% water/5% acetonitrile. At the same concentration as in the sample mixture, component A gives the UV/Vis spectrum shown in FIG. 4a with absorption maxima at 250 nm and 450 nm. At the same concentration as in the sample mixture, component B gives the UV/Vis spectrum shown in FIG. 4b with absorption maxima at 250 nm and 550 nm. At the same concentration as in the sample mixture, component C gives the UV/Vis spectrum shown in FIG. 4c with absorption maxima at 250 nm and 650 nm.

Following the analysis method, first the device collects a UV/Vis spectrum of the sample mixture prior to chromatographic separation, which is depicted in FIG. 5a. In this example, the components of the sample mixture exhibit independent behavior [i.e. their respective UV/Vis absorption behavior does not change due to the presence of the other components (such as through ionization changes, or the like)]. At this point, the collected UV/Vis spectrum could be compared to electronic library reference spectra, if so desired. In this example, the collected UV/Vis spectrum might not match any electronic library reference spectra if the electronic library reference spectra consist solely of pure compounds.

Next, the device subjects the sample to the chromatographic separation and collects a series of UV/Vis spectra from the subsamples. In this example, Component A elutes at 1.5 minutes after injection, Component B elutes at 3.5 minutes after injection, and Component C is retained by the column so strongly that it does not elute during the method run time (any component in the void volume would appear at 45 seconds). FIG. 5b depicts the example chromatographic separation by plotting absorption at 250 nm (a wavelength at which all components absorb) versus run time. At this point, the UV/Vis spectra from the individual subsamples could be compared to electronic library reference spectra, if so desired. In this example, the UV/Vis spectrum of subsample A (B) should match the electronic library reference spectrum of component A (B) if it exists in the library. Moreover, if collected with the same method as the sample, the elution times of the electronic library reference spectra could be used as another criterion for comparison to the individual UV/Vis spectra collected from the subsamples.

Next, the UV/Vis spectra collected from the subsamples after separation are co-added together to create a composite UV/Vis spectrum of the subsamples. In this example, to minimize noise, only UV/Vis spectra collected after separation with peak contributions are added into the composite UV/Vis spectrum (i.e. UV/Vis spectra collected after separation consisting only of noise are not added into the composite UV/Vis spectrum). In this example, the optical pathlength of the UV/Vis measurement does not change over the course of the method run (i.e. the changes in index of refraction over the course of the run due to changes in mobile phase composition does not affect the optical pathlength). In this example, the UV/Vis spectrum of Component A and the UV/Vis spectrum of Component B are not affected by solvent composition [i.e. the UV/Vis spectrum of Component A (B) is the same whether in 95% water/5% acetonitrile or 95% acetonitrile/5% water or any intermediary solvent composition]. FIG. 5c depicts the composite UV/Vis spectrum obtained by co-adding the individual UV/Vis spectra collected from the subsamples following chromatographic separation.

Next, the composite UV/Vis spectrum obtained by co-adding the individual UV/Vis spectra collected from the subsamples following chromatographic separation (as depicted in FIG. 5c) can be subtracted from the UV/Vis spectrum collected from the sample prior to chromatographic separation (FIG. 5a) to obtain a difference spectrum, which is depicted in FIG. 6. (Alternatively, the individual measurement profile data from the subsamples collected after separation can be subtracted from the measurement profile data of the sample to obtain the difference spectrum). In the difference spectrum, positive signal corresponds to contributions present in the measurement profile data obtained prior to separation that are more intense than in the corresponding measurement profile data collected from the subsamples after separation, such as would occur from excessive retention of a sample component so that it does not reach the detector during the method run time, sample component degradation, or insufficient retention of a sample component so that it elutes in the void volume. Similarly, in the difference spectrum, negative signal corresponds to contributions present in the measurement profile data obtained prior to separation that are less intense than in the corresponding measurement profile data collected from the subsamples after separation, such as would occur from a contaminant on the chromatographic column that eluted during the sample run, sample component degradation, or contamination in the separation solution (mobile phase). In this example, the difference spectrum shows a positive peak and, consequently, that the separation analysis of this sample is in error. Considering the source of the error, the chromatographic separation does not show a large void volume peak, so this cause can probably be ruled out. Furthermore, degradation might cause a dramatic shift in signal peak between the UV/Vis spectrum from the sample and the composite UV/Vis spectrum from the subsamples (i.e. the difference spectrum might show both a positive peak and a negative peak if a sample component degraded). Thus, in this example, the most likely source of error is that a sample component was retained by the chromatographic column and did not reach the detector during the method run time. At this point, the UV/Vis difference spectrum could be compared to electronic library reference spectra (could also compare elution times if using the same method), if so desired. In this example, the UV/Vis difference spectrum should match the electronic library reference spectrum of component C if it exists in the library.

If there is a slight discrepancy between the absorption behavior of a sample component before and after separation (such as arising from differences in solvent composition), the resulting peak shape in the difference spectrum might reveal that the observed signal profile is not due to a missing sample component or an additional contaminant but rather due to measurement artifacts. For instance, if sample component B had its peak maximum shifted to 555 nm (rather than 550 nm) during the HPLC run due to changing solvent conditions, then the resulting difference spectrum will show a positive signal at 550 nm and a negative signal at 555 nm. This type of signal pattern in a difference spectrum could be indicative of a shift in absorption profile of a sample component and could be used to rule against an actual problem with the separation (assuming that there were no other discrepancies). As another approach for discriminating between problems in separation versus measurement artifacts, the peak-width of the signal profile in the difference spectrum might be indicative since compounds will have a minimum absorption peak-width (i.e. if the signal profile in the difference spectra has a peak-width below that of the minimum peak-width for a compound, then the signal profile in the difference spectrum can be identified as arising from a measurement artifact).

To facilitate analysis, the composite UV/Vis spectrum obtained by co-adding the individual UV/Vis spectra collected from the subsamples following chromatographic separation could be calculated in real-time (i.e. the individual measurement profile data from the subsamples could be co-added immediately after collection into the composite measurement profile data without having to wait until the method run ended). Likewise, the difference spectrum could also be obtained in real-time by successively subtracting the updated composite UV/Vis spectrum collected from the subsamples after separation from the UV/Vis spectrum acquired from the sample prior to separation (i.e. the difference spectrum could be calculated continually during the method run time rather than waiting until the method run ended). (Alternatively, the difference spectrum could be obtained in real-time by successively subtracting the newly collected individual measurement profile data of the subsamples from the measurement profile data of the sample). By using real-time analysis of the difference spectrum, the instrument could determine if all the sample components reach the detector before the end of the method run. If so desired, the method run could be automatically terminated before its set end time once all the sample components reach the detector. Similarly, by using real-time analysis of the difference spectrum, the method run time could be automatically extended if all the sample components do not reach the detector by the end of its original set time in order to allow more time for any lagging sample component (or components) to reach the detector.

### Example 2

### HPLC-UV/Vis-MS of Samples

A HPLC instrument with UV/Vis diode-array detection and MS detection uses the following method to analyze samples: inject a first aliquot volume of the sample for analysis, obtain an on-line continuous-flow UV/Vis spectrum from the sample prior to any type of separation, conduct a scout separation on a short chromatographic column, obtain a series of on-line continuous-flow MS spectra from the sample (which has potentially been separated) after being subjected to the scout separation, inject a second aliquot volume of the sample for analysis, subject the sample to a comprehensive chromatographic separation, obtain a series of on-line continuous-flow UV/Vis spectra and MS spectra from the subsamples after the comprehensive separation, compare the composite UV/Vis spectra from the subsamples measured after chromatographic separation to the UV/Vis spectrum of the sample obtained before any type of chromatographic separation, compare the list of the peaks present in the MS spectra from the comprehensive separation to the list of the peaks present in the MS spectra from the scout separation. As mentioned previously, the scout separation is used to avoid possible ion suppression, which is particularly a problem if inorganic ions are present, in MS detection of sample components by gently separating the sample (as compared to a direct analysis of the sample without any separation). As mentioned previously, the comprehensive separation is used to achieve greater separation resolution and peak capacity (as compared to the scout separation).

FIG. 7 depicts a device that can conduct the method of the example. In this particular example, the HPLC instrument collects both the pre-separation and post-separation UV/Vis spectra from one flow cell and collects both the scout separation and comprehensive separation MS spectra from one ionizing source by switching flow paths (see FIG. 7). The solid arrows in FIG. 7 represent the flow path of the first sample injection, from which a UV/Vis spectrum is collected from the sample before any type of separation and MS spectra are collected from the sample after the scout separation. The dashed arrows in FIG. 7 represent the flow path of the second sample injection, from which both UV/Vis spectra and MS spectra are collected from the subsamples after comprehensive separation.

In this particular example, the HPLC instrument uses a liquid-core waveguide as the flow cell for UV/Vis measurements to minimize effects of index of refraction on optical pathlength. In this particular example, the flow cell temperature is set to 25 C during the analysis. In this particular example, the instrument injects the same volume of sample and uses the same flow rate for the two sample injections. UV/Vis spectra consist of measurement from 200 nm to 700 nm with a resolution of 2 nm. MS detection uses electrospray ionization (ESI) in positive ion mode to a triple-quad detector and scans from 100 to 600 m/z with 0.1 m/z resolution.

The HPLC method for the scout separation uses a microbore C18 column with a length of 3 cm. The HPLC method for the scout separation uses a gradient run with a 95% water/5% methanol mobile phase (buffered to pH 3) with a linear ramp to 95% methanol/5% water mobile phase (buffered to pH 3) over 90 seconds, with a 60 second hold-time before the analysis method is complete.

The HPLC method for the comprehensive separation uses a microbore C18 column with a length of 15 cm. The HPLC method for the comprehensive separation uses a gradient run with a 95% water/5% methanol mobile phase (buffered to pH 3) with a linear ramp to 95% methanol/5% water mobile phase (buffered to pH 3) over 7 minutes, with a 3 minute hold-time before the analysis method is complete.

In this example, a “blind” operator analyzes an “unknown” mixture. The sample mixture consists of two compounds, which are cationic at pH 3. The sample mixture solvent is 95% water/5% methanol (buffered to pH 3). In this example, the components of the sample mixture exhibit independent behavior [i.e. their respective UV/Vis absorption behavior does not change due to the presence of the other components (such as through ionization changes, or the like)].

Following the analysis method, the device makes a first sample injection and collects a UV/Vis spectrum from the sample (UV/Vis spectrum is not shown in the figures for this example). The UV/Vis spectrum collected from the sample could be compared to electronic library reference UV/Vis spectra, if so desired. After passing through the UV/Vis flow cell, the sample is subjected to a scout separation and MS spectra are collected afterwards. FIG. 8a depicts the example scout separation by plotting total ion current (TIC) from MS detection versus run time. From the scout chromatogram, the sample has been separated into two chromatographic peaks. Depicting the MS spectrum at peak height maximum for the first chromatographic peak (0.75 minutes), FIG. 8b shows a spectral peak at 251 m/z. Depicting the MS spectrum at peak height maximum for the second chromatographic peak (0.75 minutes), FIG. 8c shows a spectral peak at 451 m/z. The MS spectra collected from each chromatographic peak could be compared to electronic library reference MS spectra, if so desired. Moreover, if collected with the same method as the sample, the elution times of the electronic library reference MS spectra could be used as another criterion for comparison to the collected MS spectra from the sample after scout separation as well.

Next for the analysis method, the device makes a second sample injection and subjects the sample to a comprehensive separation. After the comprehensive separation, first UV/Vis spectra and then MS spectra are sequentially collected from the subsamples. FIG. 9a depicts the example comprehensive separation by plotting total ion current (TIC) from MS detection versus run time (UV/Vis measurements are not shown in the figures for this example). From the comprehensive chromatogram, the sample has been separated into two subsamples. Depicting the MS spectrum at peak height maximum for the first subsample (3.00 minutes), FIG. 9b shows a spectral peak at 251 m/z. Depicting the MS spectrum at peak height maximum for the second subsample (7.00 minutes), FIG. 9c shows a spectral peak at 483 m/z. The MS (UV/Vis) spectra collected from each subsample could be compared to electronic library reference MS (UV/Vis) spectra, if so desired. Moreover, if collected with the same method as the sample, the elution times of the electronic library reference MS (UV/Vis) spectra could be used as another criterion for comparison to the collected MS (UV/Vis) spectra from subsamples.

Next for the analysis method, the measurement profile data are compared. The comparison of the UV/Vis spectrum from the sample to the UV/Vis spectra from the subsamples can be achieved by the method described in Example 1. For the purposes of this particular example, the comparison of UV/Vis spectra measurement profile data will not be discussed.

For this particular example, the MS measurement profile data will be qualitatively compared by determining any differences between peak lists compiled from the sample (collected after scout separation) and compiled from the subsamples (collected after comprehensive separation). For the sample, a peak-picking algorithm is used on each MS spectra collected after the scout separation. Then, all the peaks observed across the individual MS spectra are compiled as a peak list. In this particular example, the peak list from the sample collected after scout separation is as follows: 251, 451 (reported in m/z units). Likewise, for the subsamples, a peak-picking algorithm is used on each MS spectra collected after the comprehensive separation. Then, all the peaks observed across the individual MS spectra are compiled as a peak list. In this particular example, the peak list from the subsamples collected after comprehensive separation is as follows: 251, 483 (reported in m/z units).

Comparing the peaks lists from the sample and the subsamples, both show a peak at 251 m/z. This is consistent with a sample component that has been properly analyzed by the analysis method. However, the peak list from the sample has a peak at 451 m/z that is not in the peak list from the subsamples. Moreover, the peak list from the subsamples has a peak at 483 m/z that is not present in the peak list from the sample. Thus, the MS measurement profile data between the sample and subsamples has differences that should be accounted for.

In MS measurement profile data comparisons, if the comprehensive separation has a peak that is not present in the scout separation, this could be due to reasons such as a contaminant peak on the comprehensive chromatographic column that eluted during the method run, ion suppression of the sample component in the scout separation, sample component degradation during the comprehensive separation, sample component degradation during the scout separation (which should not be as likely since it is a gentle separation), excessive retention on the scout chromatographic column so that the sample component does not reach the detector during the method run time (which should not be as likely since it is a gentle separation) or other reasons.

In MS measurement profile data comparisons, if the scout separation has a peak that is not present in the comprehensive separation, this could be due to reasons such as a contaminant peak on the scout chromatographic column that eluted during the method run (which should not be as likely since it is a gentle separation), ion suppression of the sample component in the comprehensive separation (which should not be as likely since it should have greater separation resolution and peak capacity), sample component degradation during the comprehensive separation, sample component degradation during the scout separation (which should not be as likely since it is a gentle separation), excessive retention on the comprehensive chromatographic column so that the sample component does not reach the detector during the method run time or other reasons.

In MS measurement profile data comparisons, if the scout separation has a peak that is not present in the comprehensive separation and also the comprehensive separation has a peak that is not present in the scout separation, this could be due to reasons such as sample component degradation during the comprehensive chromatographic separation, sample component degradation during the scout separation (which should not be as likely since it is a gentle separation), multiple problems, or other reasons.

Thus, in this particular example, sample component degradation on the comprehensive chromatographic column seems a likely cause. Examining the MS measurement profile data, the difference in MW between the two distinct MS peaks is 32, which could result from oxidation of the sample component at two different chemical sites during the comprehensive separation. Of course, the comparison of the collected UV/Vis measurement profile data from the sample and from the subsamples could be helpful in determining the cause of the problem. Of course, further investigative work could be conducted. As an example, the computer controlling the device could (automatically) repeat the sample analysis if any difference is detected from measurement profile data comparison to see if the results are consistent (if they were inconsistent, this could indicate contamination from a previous run as the cause).

Of course, multiple changes could be made to the method of analysis (and to the device, particularly if needed to suit the method of analysis) for different embodiments. As another embodiment, rather than just collecting ESI MS spectra in positive ion mode, the method could cyclically collect ESI MS spectra in positive ion mode, ESI MS spectra in negative ion mode, atmospheric pressure chemical ionization (APCI) MS spectra in positive ion mode, and APCI MS spectra in negative ion mode during the same method run (and then compare the 4 different sets of MS measurement profile data from the sample and from the subsamples). As another embodiment, MS-MS spectra (as well as higher order MS spectra) could be collected as measurement profile data (which would also increase the power of chemical identification in electronic library reference spectra searching). As another embodiment, instead of using a short chromatographic column for the scout separation, the method could use a membrane or a transient electrophoresis separation (i.e. a short electrophoresis period followed by pressure-induced flow) for the scout separation. Moreover, a device as shown in FIG. 10 could be used to obtain MS (and UV/Vis) measurement profile data from a direct injection of the sample as well as MS (and UV/Vis) measurement profile data from both a scout separation and a comprehensive separation. (The measurement of conductivity and pH of the sample could help indicate if ion suppression is possible.) Again, the invention lends itself to modifications such as that just described and others that those skilled in the art and science of separations, measurement science, or spectroscopy can easily accomplish, and therefore not depart from the scope of the invention.

### Example 3

### HPLC-UV/Vis of Manufactured Active Pharmaceutical Ingredient to Check Purity

A HPLC instrument with UV/Vis diode-array detection uses the following method to analyze sample [manufactured Active Pharmaceutical Ingredient (API)] as a quality check to determine purity: obtain a UV/Vis spectrum from the sample prior to chromatographic separation, subject the sample to a chromatographic separation, obtain a series of on-line continuous-flow UV/Vis spectra from the subsamples after the chromatographic separation, subtract the UV/Vis spectra of the subsamples measured after chromatographic separation from the UV/Vis spectrum of the sample obtained before chromatographic separation.

In this particular example, the API has an unknown impurity present. Following the analysis method, the device first collects a UV/Vis spectrum of the sample prior to separation. Comparing the collected UV/Vis spectrum of the sample to the electronic library UV/Vis reference spectrum, a difference is noted. Subtracting the library reference spectrum from the sample spectrum gives a difference spectrum. The difference spectrum is compared to library reference spectra to look for matches. In this particular example, the difference spectrum closely matches the reference spectrum of a known process impurity, which elutes at a specific time in the HPLC method.

Following the analysis method, the sample is subjected to chromatographic separation and UV/Vis spectra are collected from the subsamples. The individual UV/Vis spectra from the subsamples are subtracted from the UV/Vis spectra of the sample to create another difference spectrum. In this particular example, the difference spectrum shows a positive signal profile (corresponding to a stronger signal in the sample measurement profile data than in the measurement profile data from the subsamples). The difference spectrum has the same signal profile as previously observed when subtracting the library API reference spectrum from the sample spectrum. However, the previously suspected contaminant is known to elute during the HPLC method; thus, the contaminant is something different. From the available data of the example, the contaminant is strongly retained by the chromatographic column and does not reach the detector during the run time. With this alert, users conduct further investigations to identify the unknown contaminant. This error in separation analysis would not have been noticed by traditional HPLC analysis, which only detects subsamples after separation.

### Example 4

### CE-UV/Vis of Samples

A CE instrument with UV/Vis diode-array detection uses the following method to analyze samples: obtain a UV/Vis spectrum from the sample prior to CE separation, subject the sample to a CE separation, obtain a series of on-line continuous-flow UV/Vis spectra from the subsamples after the CE separation, subtract the UV/Vis spectra of the subsamples measured after CE separation from the UV/Vis spectrum of the sample obtained before CE separation.

In this particular example, an unknown sample mixture is analyzed with the CE run in the traditional mode (inlet has a negative electrode charge and outlet has a positive electrode charge). After obtaining a UV/Vis spectrum from the sample prior to CE separation, the sample is subjected to CE separation and UV/Vis spectra are collected from the subsamples. Following the analysis method, the individual UV/Vis spectra from the subsamples are subtracted from the UV/Vis spectra of the sample to create a difference spectrum (as mentioned previously, standardization is needed to account for differences in detector residence times). In this particular example, the difference spectrum shows a positive signal profile (corresponding to a stronger signal in the sample measurement profile data than in the measurement profile data from the subsamples). Consequently, the presence of anions with a high electrophoretic mobility is suspected and investigated.

Having described various embodiments of the present invention, it should be apparent that modifications can be made without departing from the spirit and scope of the inventions. The claims should be so read.

What is claimed is:

1. A method for analyzing a sample comprising:
a) measuring the sample to obtain measurement profile data of the sample;
b) applying a separation technique to the sample to separate it into one or more subsamples;
c) measuring at least one of the one or more subsamples to obtain measurement profile data; and
d) comparing the subsample measurement profile data to the sample measurement profile data.

2. A method according to claim 1 which further comprises utilizing the comparison between the subsample measurement profile data and the sample measurement profile data to determine the performance of the separation technique.

3. A method according to claim 1 wherein all of the subsamples are measured and all of the subsample measurement profile data is compared to the sample measurement profile data.

4. A method according to claim 1 wherein the sample measurement profile data and the subsample measurement profile data are obtained with the same type of measurement.

5. A method according to claim 1 wherein the steps a, b, and c of the method are performed by a single device.

6. A method according to claim 1 wherein the steps a, b, and c of the method are performed by one of the group comprising: stand-alone device, modular device, modified device.

7. A method according to claim 1 wherein if there is a significant difference between the subsample measurement profile data and the sample measurement profile data, the method of claim 1 is repeated.

8. A method according to claim 1 wherein if there is a significant difference between the subsample measurement profile data and the sample measurement profile data, the reason for the difference is determined.

9. A method according to claim 1 wherein the measurement profile data of each subsample is individually compared to the measurement profile data of the sample.

10. A method according to claim 1 wherein the measurement profile data of subsamples are combined to create a composite measurement profile data of the subsamples for comparison to the sample measurement profile data.

11. A method according to claim 1 wherein the difference between the subsample measurement profile data and the sample measurement profile data is determined.

12. A method according to claim 1 wherein the difference spectrum between the subsample measurement profile data and the sample measurement profile data is determined.

13. A method according to claim 1 wherein the comparison between the subsample measurement profile data and the sample measurement profile data comprises at least one of the following: the difference between peak lists, the difference in peak maxima, the difference in peak integration.

14. A method according to claim 1 wherein a chemometric technique is used to compare subsample measurement profile data to sample measurement profile data.

15. A method according to claim 1 wherein visual inspection is used to compare subsample measurement profile data to sample measurement profile data.

16. A method according to claim 1 wherein the measurement profile data receive data treatment.

17. A method according to claim 16 wherein the measurement profile data is standardized.

18. A method according to claim 16 wherein the measurement profile data is normalized.

19. A method according to claim 1 wherein the measurement profile data are compared to library reference measurement profile data.

20. A method according to claim 12 wherein the difference spectrum between the subsample measurement profile data and the sample measurement profile data is compared to one of the group comprising library reference measurement profile data, the subsample measurement profile data from the method.

21. A method according to claim 1 wherein the comparison is processed in real-time as the separation progresses.

22. A method according to claim 1 wherein the separation step and measurement step are continued if there is a significant difference between the subsample measurement profile data and the sample measurement profile data.

23. A method according to claim 1 wherein the separation step and the comparison step are terminated after determining that there is not a significant difference between the subsample measurement profile data and the sample measurement profile data.

24. A method according to claim 1 wherein a computer is used to operate at least a portion of the method.

25. A method according to claim 1 wherein automation is used for at least a portion of the method.

26. A method according to claim 1 wherein the sample measurement profile data and the subsample measurement profile data are obtained at the same device detection location.

27. A method according to claim 1 wherein the sample measurement profile data and the subsample measurement profile data are obtained at different device detection locations.

28. A method according to claim 1 wherein measurement profile data is obtained in a continuous-flow mode.

29. A method according to claim 1 wherein measurement profile data is obtained in a stopped-flow mode.

30. A method according to claim 1 wherein the separation technique is selected from the group comprising high-performance liquid chromatography, chromatography, electrophoresis, capillary electrophoresis.

31. A method according to claim 30 wherein the measurement profile data obtained by the method is selected from the group comprising ultraviolet-visible spectroscopy, mass spectrometry, evaporative light scattering detection, nitrogen chemiluminescence, nuclear magnetic resonance spectroscopy.

32. A method according to claim 1 wherein at least one specialty flow cell is used for obtaining measurement profile data.

33. A method according to claim 1 wherein at least one corrective technique is used to lower the effect of separation solution gradients on measurement profile data.

34. A method according to claim 1 wherein at least one of the steps is repeated and at least one of sample stability and sample degradation determined by comparison of the repeated steps.

35. A method according to claim 1 wherein a multi-stage separation is conducted in which subsample measurement profile data is obtained after each separation stage for comparison to each other and to sample measurement profile data.

36. A method according to claim 1 wherein more than one type of measurement profile data is obtained for both the sample and subsamples and each type of subsample measurement profile data is compared to the same type of sample measurement profile data.

37. A method according to claim 1 wherein the difference between subsample measurement profile data and sample measurement profile data is analyzed to determine if the difference is a measurement artifact.

38. A method according to claim 1 wherein the sample is subjected to a scout separation prior to obtaining measurement profile data.

39. A method according to claim 1 wherein measurement profile data is obtained from the sample, measurement profile data is obtained from the sample after subjecting the sample to a scout separation, and measurement profile data is obtained from the subsamples and comparison is made between them.

40. A method according to claim 1 wherein a diagnostic measurement is obtained from the sample to investigate the possibility of signal suppression.

41. A method according to claim 1 wherein multiple sample measurement profile data are obtained by using different sample solutions for comparison to subsample measurement profile data.

42. A method for analyzing a sample comprising:
a) measuring the sample to obtain measurement profile data of the sample;
b) applying a separation technique to the sample to separate it into one or more subsamples; and
c) measuring at least one of the one or more subsamples to obtain measurement profile data.

43. A method according to claim 42 which is performed by a single device.

44. A device for analyzing a sample comprising:
a) a means for measuring the sample to obtain measurement profile data of the sample;
b) a means for applying a separation technique to the sample to separate the sample into one or more subsamples;
c) a means for measuring at least one of the subsamples to obtain measurement profile data of; and
d) a means for comparing the subsample measurement profile data and the sample measurement profile data.

45. A device according to claim 44 wherein the comparison is done to determine the performance of the separation technique.

46. A device according to claim 44 wherein the means for comparing the subsample measurement profile data to the sample measurement profile data is a computer.

47. A device for analyzing a sample comprising:
a) a means for measuring the sample to obtain measurement profile data of the sample;
b) applying a separation technique to the sample to separate it into one or more subsamples; and
c) a means for measuring at least one of the subsamples in a specialty flow cell to obtain measurement profile data.

48. A device for analyzing a sample comprising:
a) a means for measuring the sample to obtain measurement profile data of the sample;
b) applying a separation technique to the sample to separate it into one or more subsamples; and
c) a means for measuring at least one of the subsamples at a different device detection location to obtain measurement profile data.

49. A method for analyzing a sample by parallel separations comprising:
a) applying a separation technique to the sample to separate it into one or more subsamples;
b) measuring at least one of the one or more subsamples to obtain measurement profile data;
c) repeating steps a) and b) for each separation comprising the parallel separations; and
d) comparing the subsample measurement profile data from the parallel separations to one another by using a method selected from the group comprising, comparing composite subsample measurement profile data, determining the difference spectrum between two subsample measurement profile data.
